(19) United States
(12) Patent Application Publication
(10) Pub. No.: US 2024/0373680 A1
(43) Pub. Date: Nov. 7, 2024

(54) DISPLAY DEVICE

(71) Applicant: Samsung Display Co., Ltd., Yongin-si (KR)

(72) Inventors: SUNHO KIM, Yongin-si (KR); YOOMIN KO, Yongin-si (KR); Hyewon KIM, Yongin-si (KR); JUCHAN PARK, Yongin-si (KR); PILSUK LEE, Yongin-si (KR); CHUNG SOCK CHOI, Yongin-si (KR); SUNGJIN HONG, Yongin-si (KR)

(21) Appl. No.: 18/608,667

(22) Filed: Mar. 18, 2024

(30) Foreign Application Priority Data
May 3, 2023 (KR) 10-2023-0057399

(51) Int. Cl. H10K 59/122; H10K 59/80

(52) U.S. Cl. CPC H10K 59/122; H10K 59/873

(57) ABSTRACT

A display device includes: a base layer; a light emitting element on the base layer, and including a first electrode, an intermediate layer on the first electrode, and a second electrode on the intermediate layer; a pixel definition film on the first electrode, and having a light emitting opening exposing a portion of the first electrode; a separator on the pixel definition film, and disconnecting the second electrode; and an encapsulation layer on the pixel definition film, and including: a first encapsulation layer including a first sub-layer covering the separator, a second sub-layer on the first sub-layer, and a third sub-layer on the second sub-layer; a second encapsulation layer on the first encapsulation layer, and including an organic material; and a third encapsulation layer on the second encapsulation layer, and including an inorganic material. At least one of the first sub-layer or the second sub-layer includes an organic material.

### CROSS-REFERENCE TO RELATED APPLICATIONS

The present application claims priority to and the benefit of Korean Patent Application No. 10-2023-0057399, filed on May 3, 2023, in the Korean Intellectual Property Office, the entire disclosure of which is incorporated by reference herein.

### BACKGROUND

### 1. Field

Aspects of embodiments of the present disclosure relate to a display device, and more particularly, to a display device having improved afterimage defects.

### 2. Description of Related Art

Multimedia electronic devices, such as a television (TV), a mobile phone, a tablet personal computer (PC), a computer, a navigation system, and a game console, include display panels for displaying images.

The display panel includes a light emitting element, and a circuit for driving the light emitting element. The light emitting element included in the display panel emit light beams, and generate images according to a voltage applied from the circuit. As such, an improved connection between the light emitting element and the circuit may be desired to improve the reliability of the display panel.

The above information disclosed in this Background section is for enhancement of understanding of the background of the present disclosure, and therefore, it may contain information that does not constitute prior art.

### SUMMARY

One or more embodiments of the present disclosure are directed to a display device having improved afterimage defects.

According to one or more embodiments of the present disclosure, a display device includes: a base layer; a light emitting element on the base layer, and including a first electrode, an intermediate layer on the first electrode, and a second electrode on the intermediate layer; a pixel definition film on the first electrode, and having a light emitting opening exposing a portion of the first electrode; a separator on the pixel definition film, and disconnecting the second electrode; and an encapsulation layer on the pixel definition film, and including: a first encapsulation layer including a first sub-layer covering the separator, a second sub-layer on the first sub-layer, and a third sub-layer on the second sub-layer; a second encapsulation layer on the first encapsulation layer, and including an organic material; and a third encapsulation layer on the second encapsulation layer, and including an inorganic material. At least one of the first sub-layer or the second sub-layer includes an organic material.

In an embodiment, the first encapsulation layer may include silicon carbonate (SiOCₓ).

In an embodiment, the first sub-layer may include silicon carbonate (SiOCₓ), and the second sub-layer and the third sub-layer may include the inorganic material.

In an embodiment, the second sub-layer may include silicon carbonate (SiOCₓ), and the first sub-layer and the third sub-layer may include the inorganic material.

In an embodiment, the display device may further include: a transistor; and a connection wiring line connecting the transistor and the light emitting element to each other, and including a first layer, a second layer, and a third layer. A side surface of the third layer may form a tip portion protruding from a side surface of the second layer, and the second electrode may be disconnected by the tip portion.

In an embodiment, the first sub-layer may be located on the pixel definition film, the second electrode, and the separator to cover an area between the second electrode and the separator.

In an embodiment, the second sub-layer may be in contact with the pixel definition film in an area between the second electrode and the separator.

In an embodiment, the display device may further include: a transistor; a connection wiring line connecting the transistor and the light emitting element to each other; and a metal layer between the pixel definition film and the intermediate layer. The metal layer may be electrically connected to the connection wiring line.

In an embodiment, the first sub-layer may be located on the metal layer, the second electrode, and the separator to cover an area between the second electrode and the separator.

In an embodiment, the second sub-layer may be in contact with the metal layer in an area between the second electrode and the separator.

In an embodiment, the metal layer may surround the separator in a plan view.

In an embodiment, the display device may further include a capping pattern on the transistor, the capping pattern including the same material as that of the first electrode, and the capping pattern may electrically connect the metal layer and the connection wiring line to each other.

In an embodiment, an angle between an upper surface of the second sub-layer overlapping with the second electrode and a side surface of the second sub-layer along an outer surface of the separator may be greater than an outer angle between an upper surface of the pixel definition film and the outer surface of the separator.

According to one or more embodiments of the present disclosure, a display device includes: a base layer; a transistor; a light emitting element on the base layer, and including a first electrode, an intermediate layer on the first electrode, and a second electrode on the intermediate layer; a connection wiring line connecting the transistor and the light emitting element to each other; a pixel definition film on the first electrode, and having a light emitting opening exposing a portion of the first electrode; a separator on the pixel definition film, and disconnecting the second electrode; a metal layer on the pixel definition film, and surrounding the separator in a plan view; and an encapsulation layer on the pixel definition film, and including: a first encapsulation layer including silicon carbonate (SiOCₓ); a second encapsulation layer on the first encapsulation layer, and including an organic material; and a third encapsulation layer on the second encapsulation layer, and including an inorganic material.

In an embodiment, the first encapsulation layer may include a first sub-layer covering the separator, a second sub-layer on the first sub-layer, and a third sub-layer on the second sub-layer, and at least one of the first sub-layer or the second sub-layer may include the silicon carbonate (SiOCₓ).

In an embodiment, the first sub-layer may include the silicon carbonate (SiOCₓ), and the second sub-layer and the third sub-layer may include inorganic materials.

In an embodiment, the second sub-layer may include the silicon carbonate (SiOCₓ), and the first sub-layer and the third sub-layer may include inorganic materials.

In an embodiment, the first sub-layer may be located on the metal layer, the second electrode, and the separator to cover an area between the second electrode and the separator.

In an embodiment, the second sub-layer may be in contact with the metal layer in an area between the second electrode and the separator.

According to one or more embodiments of the present disclosure, a display device includes: a base layer; a light emitting element on the base layer, and including a first electrode, an intermediate layer on the first electrode, and a second electrode on the intermediate layer; a pixel definition film on the first electrode, and having a light emitting opening exposing a portion of the first electrode; a separator on the pixel definition film, and disconnecting the second electrode; and an encapsulation layer on the pixel definition film, and including a first encapsulation layer, a second encapsulation layer, and a third encapsulation layer stacked in a thickness direction of the base layer. The first encapsulation layer includes a first sub-layer, a second sub-layer, and a third sub-layer sequentially stacked in the thickness direction of the base layer, and at least one of the first sub-layer or the second sub-layer includes silicon carbonate (SiOCₓ). An angle between an upper surface of the second sub-layer overlapping with the second electrode and a side surface of the second sub-layer along an outer surface of the separator is greater than an outer angle between an upper surface of the pixel definition film and the outer surface of the separator.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a block diagram of a display device according to an embodiment of the present disclosure.

FIGS. 2A and 2B are equivalent circuit diagrams of a pixel according to one or more embodiments of the present disclosure.

FIGS. 3A and 3B are schematic plan views illustrating a display panel according to one or more embodiments of the present disclosure.

FIGS. 4A-4D are enlarged plan views of a partial area of the display panel according to one or more embodiments of the present disclosure.

FIG. 5 is a cross-sectional view of the display panel according to an embodiment of the present disclosure.

FIG. 6 is an enlarged cross-sectional view of a partial area of the display panel according to an embodiment of the present disclosure.

FIG. 7 is a cross-sectional view of the display panel according to an embodiment of the present disclosure.

FIG. 8 is a cross-sectional view of the display panel according to an embodiment of the present disclosure.

FIGS. 9-14 are enlarged cross-sectional views of a partial area of the display panel according to one or more embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

As used herein, the terms “part” and “unit” may refer to a software component or a hardware component that performs a specific function. The hardware component may include, for example, a field-programmable gate array (FPGA) or an application-specific integrated circuit (ASIC). The software component may refer to executable code and/or data used by the executable code in an addressable storage medium. Thus, the software components may be, for example, object-oriented software components, class components, and/or task components, and may include processes, functions, attributes, procedures, subroutines, program code segments, drivers, firmwares, microcodes, circuits, data, database, data structures, tables, arrays, or variables.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

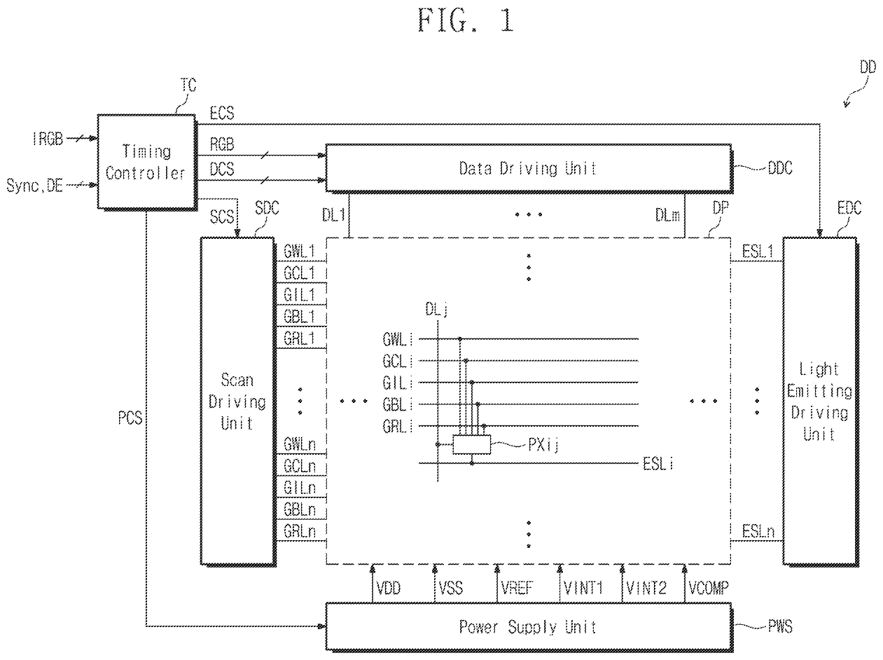

FIG. 1 is a block diagram of a display device DD according to an embodiment of the present disclosure.

Referring to FIG. 1, the display device DD may include a display panel DP, panel driving units (e.g., panel drivers or panel driving circuits) SDC, EDC, and DDC, a power supply unit (e.g., a power supply) PWS, and a timing controller TC. In an embodiment, the display panel DP may be a light emitting display panel. The light emitting display panel may include an organic light emitting display panel, an inorganic light emitting display panel, and/or a quantum dot light emitting display panel. For convenience, the organic light emitting display panel will be mainly described in more detail hereinafter as a representative example. The panel driving units SDC, EDC, and DDC may include a scan driving unit (e.g., a scan driver or a scan driving circuit) SDC, a light emitting driving unit (e.g., a light emitting driver or a light emitting driving circuit) EDC, and a data driving unit (e.g., a data driver or a data driving circuit) DDC.

The display panel DP may include scan lines GWL1 to GWLn, GCL1 to GCLn, GIL1 to GILn, GBL1 to GBLn, and GRL1 to GRLn, light emitting lines ESL1 to ESLn, and data lines DL1 to DLm (where m and n are integers greater than 1). The display panel DP may include a plurality of pixels connected to the scan lines GWL1 to GWLn, GCL1 to GCLn, GIL1 to GILn, GBL1 to GBLn, and GRL1 to GRLn, the light emitting lines ESL1 to ESLn, and the data lines DL1 to DLm.

For example, a pixel PXij (where i and j are integers greater than or equal to 1) positioned at an i^{th} horizontal line (e.g., an i^{th} pixel row) and a j^{th} vertical line (e.g., a j^{th} pixel column) may be connected to an i^{th} first scan line (e.g., a writing scan line) GWLi, an i^{th} second scan line (e.g., a compensation scan line) GCLi, an i^{th} third scan line (e.g., a first initialization scan line) GILi, an i^{th} fourth scan line (e.g., a second initialization scan line) GBLi, an i^{th} fifth scan line (e.g., a reset scan line) GRLi, a j^{th} data line DLj, and an i^{th} light emitting line ESLi.

The pixel PXij may include a plurality of light emitting elements, a plurality of transistors, and a plurality of capacitors. The pixel PXij may receive, through the power supply unit PWS, a first power voltage VDD, a second power voltage VSS, a third power voltage (e.g., a reference voltage) VREF, a fourth power voltage (e.g., a first initialization voltage) VINT1, a fifth power voltage (e.g., a second initialization voltage) VINT2, and a sixth power voltage (e.g., a compensation voltage) VCOMP.

Voltage values of the first power voltage VDD and the second power voltage VSS may be determined (e.g., may be set) such that a current flows in the light emitting element to emit a light beam. For example, the first power voltage VDD may be a higher voltage than that of the second power voltage VSS.

The third power voltage VREF may be a voltage for initializing a gate of a driving transistor included in the pixel PXij. The third power voltage VREF may be used to implement a grayscale (e.g., a predetermined grayscale) using a voltage difference between the third power voltage VREF and a data signal. As such, the third power voltage VREF may have a suitable voltage (e.g., a predetermined voltage) within a voltage range of the data signal.

The fourth power voltage VINT1 may be a voltage for initializing a capacitor included in the pixel PXij. The fourth power voltage VINT1 may have a lower voltage than that of the third power voltage VREF. For example, the fourth power voltage VINT1 may have a voltage lower than a difference between the third power voltage VREF and a threshold voltage of the driving transistor. However, the present disclosure is not limited thereto.

The fifth power voltage VINT2 may be a voltage for initializing a cathode of the light emitting element included in the pixel PXij. The fifth power voltage VINT2 may have a voltage lower than that of the first power voltage VDD or the fourth power voltage VINT1, or may have a voltage similar to or equal to that of the third power voltage VREF. However, the present disclosure is not limited thereto, and the fifth power voltage VINT2 may have a voltage similar to or equal to that of the first power voltage VDD.

The sixth power voltage VCOMP may supply a current (e.g., a predetermined current) to the driving transistor when the threshold voltage of the driving transistor is compensated for.

FIG. 1 illustrates that all of the first to sixth power voltages VDD, VSS, VREF, VINT1, VINT2, and VCOMP are supplied from the power supply unit PWS, but the present disclosure is not limited thereto. For example, both of the first power voltage VDD and the second power voltage VSS may be supplied regardless of a structure of the pixel PXij, and at least one of the third power voltage VREF, the fourth power voltage VINT1, the fifth power voltage VINT2, and/or the sixth power voltage VCOMP may not be supplied according to the structure of the pixel PXij.

In an embodiment of the present disclosure, signal lines connected to the pixel PXij may be variously modified to correspond to a circuit structure of the pixel PXij.

The scan driving unit SDC may receive a first control signal SCS from the timing controller TC, and may supply, based on the first control signal SCS, a scan signal to the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The scan signal may have a voltage at which the transistors that receive the scan signal may be turned on. For example, the scan signal supplied to a P-type transistor may have a logic low level, and the scan signal supplied to an N-type transistor may have a logic high level. Hereinafter, the phrase “the scan signal is supplied” may be understood as the scan signal that is supplied at a logic level (e.g., a turn on level) at which the transistor controlled by the scan signal is turned on.

In FIG. 1, for convenience of illustration, the scan driving unit SDC is illustrated as a single component, but the present disclosure is not limited thereto. According to an embodiment, a plurality of scan driving units (e.g., a plurality of scan drivers or scan driving circuits) may be included to supply the scan signals to the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The light emitting driving unit EDC may supply a light emitting signal to the light emitting lines ESL1 to ESLn based on a second control signal ECS from the timing controller TC. For example, the light emitting signal may be sequentially supplied to the light emitting lines ESL1 to ESLn.

The transistors connected to the light emitting lines ESL1 to ESLn according to one or more embodiments of the present disclosure may be configured as N-type transistors. In this case, the light emitting signal supplied to the light emitting lines ESL1 to ESLn may have a gate-off voltage. The transistors that receive the light emitting signal may be turned off when the light emitting signal is supplied, and may be turned on in other cases.

The second control signal ECS may include a light emitting start signal and clock signals. The light emitting driving unit EDC may be implemented as a shift register that sequentially shifts the light emitting start signal having a pulse form using the clock signals to sequentially generate and output the light emitting signal having a pulse form.

The data driving unit DDC may receive a third control signal DCS and image data RGB from the timing controller TC. The data driving unit DDC may convert the image data RGB having a digital form into an analog data signal (e.g., a data signal). The data driving unit DDC may supply the data signal to the data lines DL1 to DLm to correspond to the third control signal DCS.

The third control signal DCS may include a data enable signal, a horizontal start signal, a data clock signal, and the like to instruct output of a valid data signal. For example, the data driving unit DDC may include a shift register that generates a sampling signal by shifting the horizontal start signal in synchronization with the data clock signal, a latch that latches the image data RGB in response to the sampling signal, a digital-to-analog converter (or a decoder) that converts the latched image data (e.g., data having a digital form) into analog data signals, and buffers (or amplifiers) that output the data signals to the data lines DL1 to DLm.

The power supply unit PWS may supply, to the display panel DP, the first power voltage VDD, the second power voltage VSS, and the third power voltage VREF for driving the pixel PXij. Further, the power supply unit PWS may supply at least one of the fourth power voltage VINT1, the fifth power voltage VINT2, and/or the sixth power voltage VCOMP to the display panel DP.

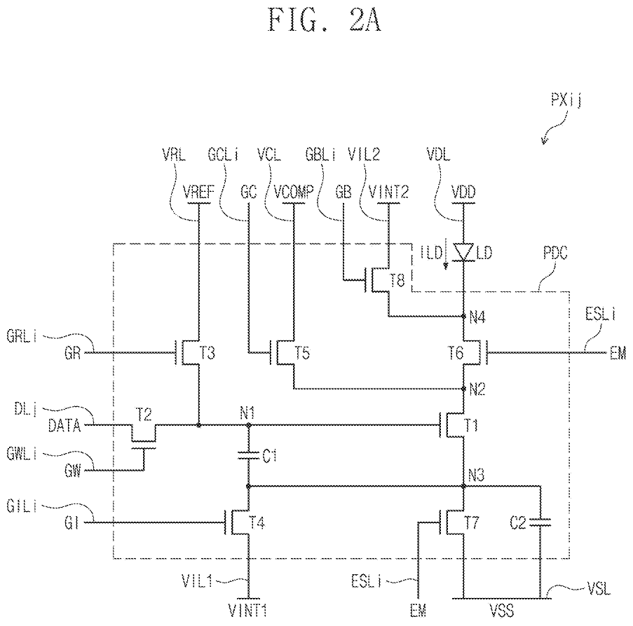

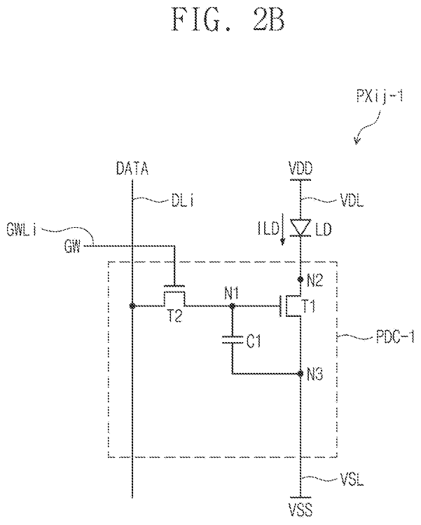

For example, the power supply unit PWS may supply, to the display panel DP, the first power voltage VDD, the second power voltage VSS, the third power voltage VREF, the fourth power voltage VINT1, the fifth power voltage VINT2, and the sixth power voltage VCOMP via a first power line VDL (e.g., see FIG. 2A), a second power line VSL, a third power line (e.g., a reference voltage line) VRL, a fourth power line (e.g., a first initialization voltage line) VIL1, a fifth power line (e.g., a second initialization voltage line) VIL2, and a sixth power line (e.g., a compensation voltage line) VCL.

The power supply unit PWS may be implemented as a power management integrated circuit, but the present disclosure is not limited thereto.

The timing controller TC may generate the first control signal SCS, the second control signal ECS, the third control signal DCS, and a fourth control signal PCS based on input image data IRGB, a synchronization signal Sync (e.g., a vertical sync signal, a horizontal sync signal, and the like), a data enable signal DE, a clock signal, and the like. The first control signal SCS may be supplied to the scan driving unit SDC, the second control signal ECS may be supplied to the light emitting driving unit EDC, the third control signal DCS may be supplied to the data driving unit DDC, and the fourth control signal PCS may be supplied to the power supply unit PWS. The timing controller TC may rearrange the input image data IRGB to correspond to the arrangement of the pixels PXij in the display panel DP to generate the image data RGB (e.g., frame data).

The scan driving unit SDC, the light emitting driving unit EDC, the data driving unit DDC, the power supply unit PWS, and/or the timing controller TC may be directly formed in the display panel DP, or may be provided in the form of a separate driving chip to be connected to the display panel DP. Further, at least two from among the scan driving unit SDC, the light emitting driving unit EDC, the data driving unit DDC, the power supply unit PWS, and the timing controller TC may be provided together as one driving chip. For example, the data driving unit DDC and the timing controller TC may be provided together as one driving chip.

A structure of the display device DD according to one or more embodiments has been described above with reference to FIG. 1, but the display device DD according to embodiments of the present disclosure is not limited thereto. Signal lines may be further added or omitted according to the configuration of the pixel. Further, a connection relationship between one pixel and the signal lines may be variously modified as needed or desired. When one of the signal lines is omitted, the omitted signal line may be replaced with another signal line.

FIGS. 2A and 2B are equivalent circuit diagrams of a pixel according to one or more embodiments of the present disclosure. FIGS. 2A and 2B illustratively show equivalent circuit diagrams of the pixels PXij and PXij-1 connected to the i^{th} first scan line GWLi (hereinafter, referred to as a first scan line) and the j^{th} data line DLj (hereinafter, referred to as a data line).

Referring to FIG. 2A, in an embodiment, the pixel PXij includes a light emitting element LD and a pixel driving unit (e.g., a pixel driving circuit) PDC. The light emitting element LD is connected to the first power line VDL and the pixel driving unit PDC.

The pixel driving unit PDC may be connected to the plurality of scan lines GWLi, GCLi, GILi, GBLi, and GRLi, the data line DLj, the light emitting line ESLi, and the plurality of power voltage lines VDL, VSL, VIL1, VIL2, VRL, and VCL. The pixel driving unit PDC may include first to eighth transistors T1, T2, T3, T4, T5, T6, T7, and T8, a first capacitor C1, and a second capacitor C2. Hereinafter, for convenience, an embodiment in which all of the first to eighth transistors T1, T2, T3, T4, T5, T6, T7, and T8 are N-type transistors may be described in more detail as a representative example. However, the present disclosure is not limited thereto. In other embodiments, some of the first to eighth transistors T1 to T8 may be N-type transistors, and the others may be P-type transistors. In other embodiments, all of the first to eighth transistors T1 to T8 may be P-type transistors. As such, the present disclosure is not limited to any specific embodiment.

A gate of the first transistor T1 may be connected to a first node N1. A first electrode of the first transistor T1 may be connected to a second node N2, and a second electrode thereof may be connected to a third node N3. The first transistor T1 may be a driving transistor. The first transistor T1 may control a driving current ILD flowing from the first power line VDL via the light emitting element LD to the second power line VSL to correspond to a voltage of the first node N1. In this case, the first power voltage VDD may have a voltage having a higher potential than that of the second power voltage VSS.

As used herein, the phrase “electrically connected between the transistor and the signal line or between the transistor and the transistor” may mean that “a source, a drain, and a gate of the transistor have an integral shape with a signal line or are connected through a connection electrode”.

The second transistor T2 may include a gate connected to the writing scan line GWLi, a first electrode connected to the data line DLj, and a second electrode connected to the first node N1. The second transistor T2 may supply a data signal DATA to the first node N1 in response to a writing scan signal GW transmitted through the writing scan line GWLi. The second transistor T2 may be turned on when the writing scan signal GW is supplied to the writing scan line GWLi, and thus, may electrically connect the data line DLj and the first node N1 to each other.

The third transistor T3 may be connected between the first node N1 and the reference voltage line VRL. A first electrode of the third transistor T3 may receive the reference voltage VREF through the reference voltage line VRL, and a second electrode of the third transistor T3 may be connected to the first node N1. In an embodiment, a gate of the third transistor T3 may receive a reset scan signal GR through the i^{th} fifth scan line GRLi. The third transistor T3 may be turned on when the reset scan signal GR is supplied to the reset scan line GRLi, and thus, may provide the reference voltage VREF to the first node N1.

The fourth transistor T4 may be connected between the third node N3 and the first initialization voltage line VIL1. A first electrode of the fourth transistor T4 may be connected to the third node N3, and a second electrode of the fourth transistor T4 may be connected to the first initialization voltage line VIL1 that provides the first initialization voltage VINT1. The fourth transistor T4 may be referred to as a first initialization transistor. A gate of the fourth transistor T4 may receive a first initialization scan signal GI through the i^{th} third scan line GILi. The fourth transistor T4 may be turned on when the first initialization scan signal GI is supplied to the first initialization scan line GILi, and may supply the first initialization voltage VINT1 to the third node N3.

The fifth transistor T5 may be connected between the compensation voltage line VCL and the second node N2. A first electrode of the fifth transistor T5 may receive the compensation voltage VCOMP through the compensation voltage line VCL, and a second electrode of the fifth transistor T5 may be connected to the second node N2 and electrically connected to the first electrode of the first transistor T1. A gate of the fifth transistor T5 may receive a compensation scan signal GC through the i^{th} second scan line GCLi. The fifth transistor T5 may be turned on when the compensation scan signal GC is supplied to the compensation scan line GCLi, and may provide the compensation voltage VCOMP to the second node N2, and thus, a threshold voltage of the first transistor T1 may be compensated for during a compensation period.

The sixth transistor T6 may be connected between the first transistor T1 and the light emitting element LD. In more detail, a gate of the sixth transistor T6 may receive a light emitting signal EM through the i^{th} light emitting line ESLi (hereinafter, referred to as a light emitting line). A first electrode of the sixth transistor T6 may be connected to the cathode of the light emitting element LD through a fourth node N4, and a second electrode of the sixth transistor T6 may be connected to the first electrode of the first transistor T1 through the second node N2. The sixth transistor T6 may be referred to as a first light emitting control transistor. When the light emitting signal EM is supplied to the light emitting line ESLi, the sixth transistor T6 may be turned on to electrically connect the light emitting element LD and the first transistor T1 to each other.

The seventh transistor T7 may be connected between the second power line VSL and the third node N3. A first electrode of the seventh transistor T7 may be connected to the second electrode of the first transistor T1 through the third node N3, and a second electrode of the seventh transistor T7 may receive the second power voltage VSS through the second power line VSL. A gate of the seventh transistor T7 may be electrically connected to the light emitting line ESLi. The seventh transistor T7 may be referred to as a second light emitting control transistor. When the light emitting signal EM is supplied to the light emitting line ESLi, the seventh transistor T7 may be turned on to electrically connect the second electrode of the first transistor T1 and the second power line VSL to each other.

In an embodiment, FIG. 2A shows that the sixth transistor T6 and the seventh transistor T7 are connected to the same light emitting line ESLi and are turned on through the same light emitting signal EM, but the present disclosure is not limited thereto, and the sixth transistor T6 and the seventh transistor T7 may be independently turned on by different signals that are distinct from each other. Further, in an embodiment of the present disclosure, in the pixel driving unit PDC, any one of the sixth transistor T6 and/or the seventh transistor T7 may be omitted as needed or desired.

The eighth transistor T8 may be connected between the second initialization voltage line VIL2 and the fourth node N4. The eighth transistor T8 may include a gate connected to the i^{th} fourth scan line GBLi, a first electrode connected to the second initialization voltage line VIL2, and a second electrode connected to the fourth node N4. The eighth transistor T8 may be referred to as a second initialization transistor. The eighth transistor T8 may supply the second initialization voltage VINT2 to the fourth node N4 corresponding to the cathode of the light emitting element LD in response to a second initialization scan signal GB transmitted through the second initialization scan line GBLi. The cathode of the light emitting element LD may be initialized by the second initialization voltage VINT2.

In an embodiment, some of the second to eighth transistors T2, T3, T4, T5, T6, T7, and T8 may be concurrently or substantially simultaneously turned on with each other through the same scan signal. For example, the eighth transistor T8 and the fifth transistor T5 may be concurrently or substantially simultaneously turned on with each other through the same scan signal. For example, the eighth transistor T8 and the fifth transistor T5 may be operated by the same compensation scan signal GC. The eighth transistor T8 and the fifth transistor T5 may be concurrently or substantially simultaneously turned on/off with each other by the same compensation scan signal GC. In this case, the compensation scan line GCLi and the second initialization scan line GBLi may be provided or substantially provided as a single scan line. Accordingly, the initialization of the cathode of the light emitting element LD and compensation of the threshold voltage of the first transistor T1 may be performed at the same or substantially the same timing. However, the present disclosure is not limited thereto.

Further, according to an embodiment of the present disclosure, the initialization of the cathode of the light emitting element LD and the compensation of the threshold voltage of the first transistor T1 may be performed by applying the same power voltage. For example, the compensation voltage line VCL and the second initialization voltage line VIL2 may be provided or substantially provided as a single power voltage line. In this case, the initialization operation of the cathode and the compensation operation of the driving transistor may be performed using one power voltage, and thus, the design of the driving unit may be simplified. However, the present disclosure is not limited thereto.

The first capacitor C1 may be disposed between the first node N1 and the third node N3. The first capacitor C1 may store a difference voltage between the first node N1 and the third node N3. The first capacitor C1 may be referred to as a storage capacitor.

The second capacitor C2 may be disposed between the third node N3 and the second power line VSL. One electrode of the second capacitor C2 may be connected to the second power line VSL that receives the second power voltage VSS, and the other electrode of the second capacitor C2 may be connected to the third node N3. The second capacitor C2 may store charges corresponding to a voltage difference between the second power voltage VSS and the third node N3. The second capacitor C2 may be referred to as a hold capacitor. The second capacitor C2 may have a higher storage capacity than that of the first capacitor C1. Accordingly, the second capacitor C2 may minimize or reduce a change in the voltage of the third node N3 in response to a change in the voltage of the first node N1.

In an embodiment, the light emitting element LD may be connected to the pixel driving unit PDC through the fourth node N4. The light emitting element LD may include an anode connected to the first power line VDL, and a cathode corresponding to the fourth node N4. In an embodiment, the light emitting element LD may be connected to the pixel driving unit PDC through the cathode. In other words, in the pixel PXij according to an embodiment of the present disclosure, a connection node through which the light emitting element LD and the pixel driving unit PDC are connected to each other may be the fourth node N4, and the fourth node N4 may correspond to a connection node between the first electrode of the sixth transistor T6 and the cathode of the light emitting element LD. Accordingly, a potential of the fourth node N4 may correspond to or substantially correspond to a potential of the cathode of the light emitting element LD.

In more detail, the anode of the light emitting element LD may be connected to the first power line VDL to receive the first power voltage VDD that is a constant voltage. The cathode of the light emitting element LD may be connected to the first transistor T1 through the sixth transistor T6. In other words, in an embodiment in which the first to eighth transistors T1 to T8 are N-type transistors, a potential of the third node N3 corresponding to the source of the first transistor T1 that is the driving transistor may not be directly affected by characteristics of the light emitting element LD. Thus, even when the light emitting element LD is degraded, effects on the gate-source voltages Vgs of the transistors constituting the pixel driving unit PDC, particularly, on the driving transistors, may be reduced. Thus, because the amount of change in a driving current due to the degradation of the light emitting element LD may be reduced, afterimage defects of the display panel may be reduced as a usage time increases, and the lifetime thereof may be improved.

Referring to FIG. 2B, in another embodiment, the pixel PXij−1 may include a pixel driving unit (e.g., a pixel driving circuit) PDC−1 including two transistors T1 and T2 and one capacitor C1. The pixel driving unit PDC−1 may be connected to the light emitting element LD, the writing scan line GWLi, the data line DLj, and the second power line VSL. The pixel driving unit PDC−1 illustrated in FIG. 2B may correspond to a pixel driving unit (e.g., a pixel driving circuit) in which the third to eighth transistors T3 to T8 and the second capacitor C2 are omitted from the pixel driving unit PDC described above with reference to FIG. 2A.

The first and second transistors T1 and T2 may be of an N-type or a P-type. Hereinafter, an embodiment in which the first and second transistors T1 and T2 are N-type transistors may be described in more detail as a representative example.

The first transistor T1 may include a gate connected to the first node N1, a first electrode connected to the second node N2, and a second electrode connected to the third node N3. The second node N2 may be connected to the first power line VDL side of the first transistor T1, and the third node N3 may be connected to the second power line VSL side of the first transistor T1. The first transistor T1 is connected to the light emitting element LD through the second node N2, and connected to the second power line VSL through the third node N3. The first transistor T1 may be a driving transistor.

The second transistor T2 may include a gate that receives the writing scan signal GW through the writing scan line GWLi, a first electrode connected to the data line DLi, and a second electrode connected to the first node N1. The second transistor T2 may supply the data signal DATA to the first node N1 in response to the writing scan signal GW transmitted through the writing scan line GWLi.

The capacitor C1 may include an electrode connected to the first node N1 and an electrode connected to the third node N3. The capacitor C1 may store the data signal DATA transmitted to the first node N1.

The light emitting element LD may include the anode and the cathode. In an embodiment, the anode of the light emitting element LD is connected to the first power line VDL, and the cathode of the light emitting element LD is connected to the pixel driving unit PDC−1 through the second node N2. In an embodiment, the cathode of the light emitting element LD may be connected to the first transistor T1. The light emitting element LD may emit a light beam in response to the amount of a current ILD flowing through the first transistor T1 of the pixel driving unit PDC−1.

In an embodiment in which the first and second transistors T1 and T2 are N-type transistors, the second node N2 through which the cathode of the light emitting element LD and the pixel driving unit PDC−1 are connected to each other may correspond to a drain of the first transistor T1. In other words, a change in the gate-source voltage Vgs of the first transistor T1 caused by the light emitting element LD may be prevented or substantially prevented. Accordingly, because the amount of change in the driving current ILD due to the degradation of the light emitting element LD may be reduced, afterimage defects of the display panel may be reduced as a usage time increases, and the lifetime thereof may be improved.

As described above, FIGS. 2A and 2B illustrate circuits for the pixel driving units PDC and PDC−1 according to some embodiments of the present disclosure. When the display panel according to an embodiment of the present disclosure is a circuit connected to the cathode of the light emitting element LD, the number or arrangement of the transistors and the number or arrangement of the capacitors may be variously modified, and thus, the present disclosure is not limited to any particular embodiment.

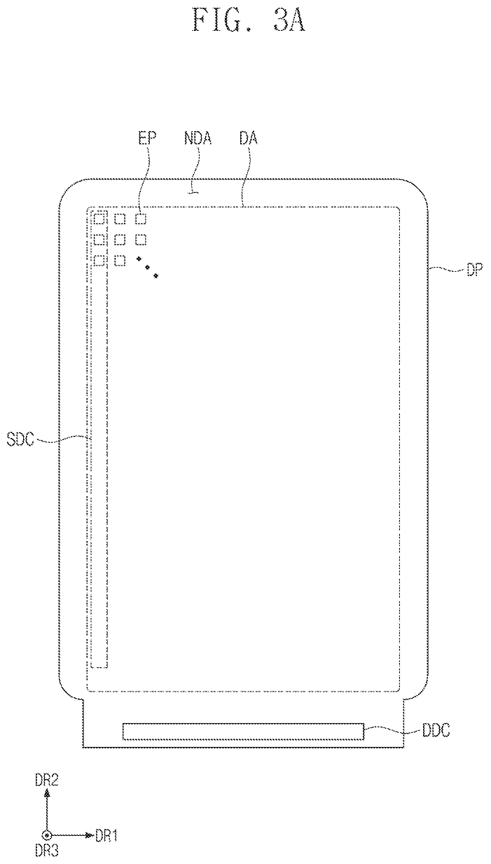

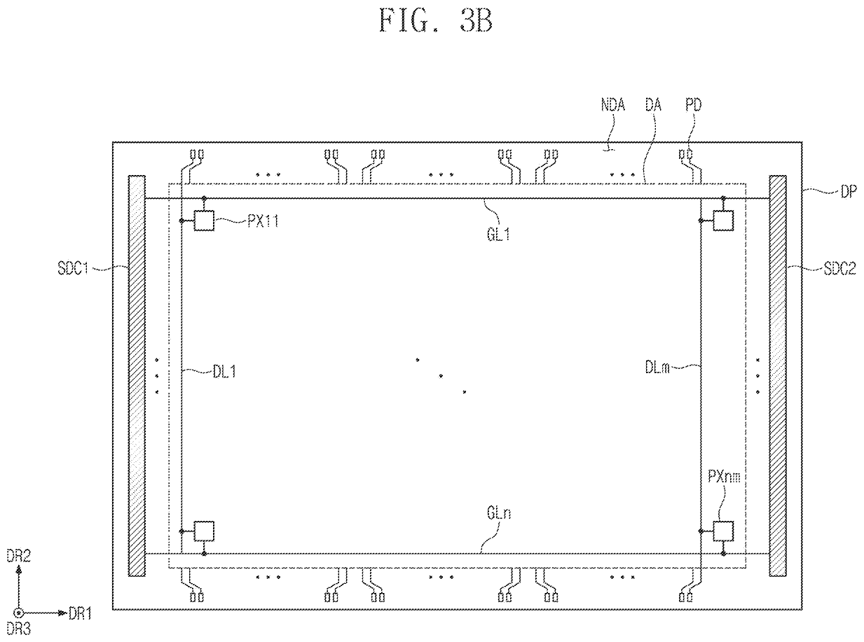

FIGS. 3A and 3B are schematic plan views illustrating the display panel DP according to one or more embodiments of the present disclosure. In FIGS. 3A and 3B, some components may be omitted for convenience of illustration.

Referring to FIG. 3A, the display panel DP according to an embodiment may be divided into a display area DA and a peripheral area (e.g., a non-display area) NDA. The display area DA may include a plurality of light emitting units (e.g., light emitting elements) EP.

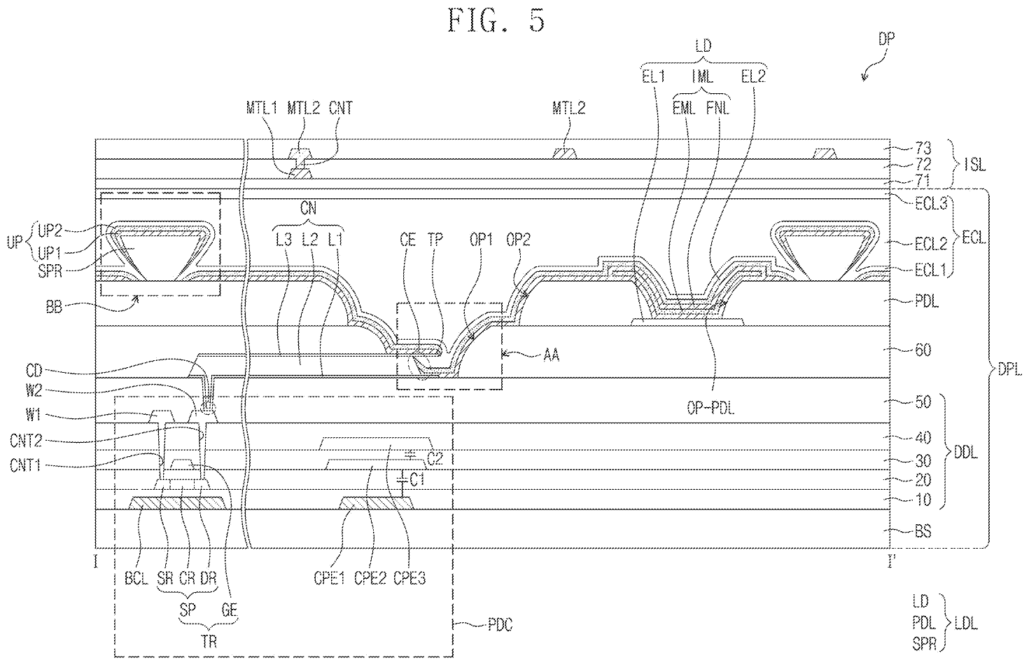

The light emitting units EP may be areas for emitting light beams by the pixels PXij (e.g., see FIG. 1). In more detail, each of the light emitting units EP may correspond to a light emitting opening OP-PDL (e.g., see FIG. 5), which will be described in more detail below.

The peripheral area NDA may be disposed adjacent to the display area DA. In an embodiment, the peripheral area NDA may have a shape surrounding (e.g., around a periphery of) an edge of the display area DA. However, the present disclosure is not limited thereto, and the peripheral area NDA may be disposed on one side of the display area DA, or may be omitted as needed or desired.

In an embodiment, as illustrated in FIG. 3A, the scan driving unit SDC and the data driving unit DDC may be mounted on the display panel DP. In an embodiment, the scan driving unit SDC may be disposed in the display area DA, and the data driving unit DDC may be disposed in the peripheral area NDA. The scan driving unit SDC may overlap with at least some of the plurality of light emitting units EP arranged in the display area DA on a plane (e.g., in a plan view). Because the scan driving unit SDC may be disposed in the display area DA, an area of the peripheral area NDA may be reduced as compared to a display panel according to a comparative example in which the scan driving unit is disposed in the peripheral area, and thus, the display device having a thinner bezel may be implemented.

In some embodiments, unlike that illustrated in FIG. 3A, the scan driving unit SDC may be provided as two distinct parts. In this case, the two scan driving units SDC may be spaced apart from each other in a left-right direction with a center of the display area DA interposed therebetween. In another embodiment, the scan driving units SDC may be provided as two or more scan driving units SDC, but the present disclosure is not limited to any particular embodiment.

FIG. 3A illustrates an example of the display panel in which the data driving unit DDC is disposed in the peripheral area NDA. In some embodiments, the data driving unit DDC may be disposed in the display area DA. In this case, some of the light emitting units EP arranged in the display area DA may overlap with the data driving unit DDC on a plane (e.g., in a plan view).

In an embodiment, the data driving unit DDC may be provided in the form of a separate driving chip independent of the display panel DP, and connected to the display panel DP. However, the present disclosure is not limited thereto, and the data driving unit DDC may be formed in the same or substantially the same process as that of the scan driving unit SDC to constitute the display panel DP.

Referring to FIG. 3B, in some embodiments, a length of the display panel DP in a first direction DR1 may be greater than a length of the display panel DP in a second direction DR2. In an embodiment, the display panel DP may include a plurality of scan driving units (e.g., a plurality of scan drivers or scan driving circuits) SDC1 and SDC2. For example, as shown in FIG. 3B, in some embodiments, the scan driving units SDC1 and SDC2 include a first scan driving unit (e.g., a first scan driver or scan driving circuit) SDC1 and a second scan driving unit (e.g., a second scan driver or scan driving circuit) SDC2 spaced apart from each other in the first direction DR1.

The first scan driving unit SDC1 may be connected to some of the scan lines GL1 to GLn, and the second scan driving unit SDC2 may be connected to the others of the scan lines GL1 to GLn. For example, the first scan driving unit SDC1 may be connected to odd-numbered scan lines from among the scan lines GL1 to GLn, and the second scan driving unit SDC2 may be connected to even-numbered scan lines from among the scan lines GL1 to GLn.

For convenience of illustration, FIG. 3B illustrates pads PD of the data lines DL1 to DLm. The pads PD may be defined at ends of the data lines DL1 to DLm. The data lines DL1 to DLm may be connected to the data driving unit DDC (e.g., see FIG. 1) through the pads PD.

According to one or more embodiments of the present disclosure, the pads PD may be dividedly arranged at positions of the peripheral area NDA, and may be spaced apart from each other with the display area DA interposed therebetween. For example, some of the pads PD may be arranged on an upper side, or in other words, on a side adjacent to the first scan line GL1 from among the scan lines GL1 to GLn. Others of the pads PD may be arranged on a lower side, or in other words, on a side adjacent to the last scan line GLn from among the scan lines GL1 to GLn. In an embodiment, the pads PD connected to odd-numbered data lines from among the data lines DL1 to DLm may be arranged on the upper side, and the pads PD connected to even-numbered data lines from among the data lines DL1 to DLm may be arranged on the lower side.

The display panel DP may include a plurality of upper data driving units (e.g., upper data drivers or data driving circuits) connected to the pads PD arranged on the upper side, and/or a plurality of lower data driving units (e.g., lower data drivers or data driving circuits) connected to the pads PD arranged on the lower side. However, the present disclosure is not limited thereto, and the display panel DP may also include one upper data driving unit connected to the pads PD arranged on the upper side, and/or one lower data driving unit connected to the pads PD arranged on the lower side. The pads PD according to an embodiment of the present disclosure may be disposed on one side (e.g., on only one side) of the display panel DP, and connected to a single data driving unit, but the present disclosure is not limited thereto.

Further, in some embodiments, like that described above with reference to FIG. 3A, in the display panel DP illustrated in FIG. 3B, the scan driving unit and/or the data driving unit may be arranged in the display area DA. Accordingly, some of the light emitting units arranged in the display area DA may overlap with the scan driving unit and/or the data driving unit on a plane (e.g., in a plan view).

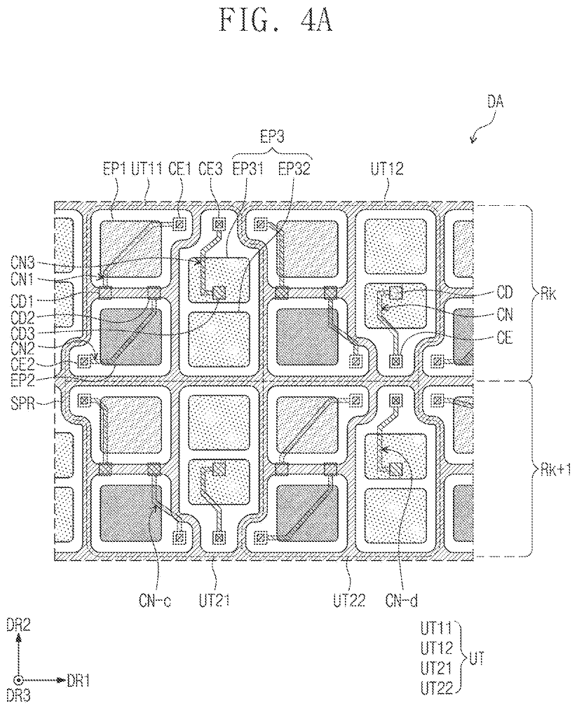

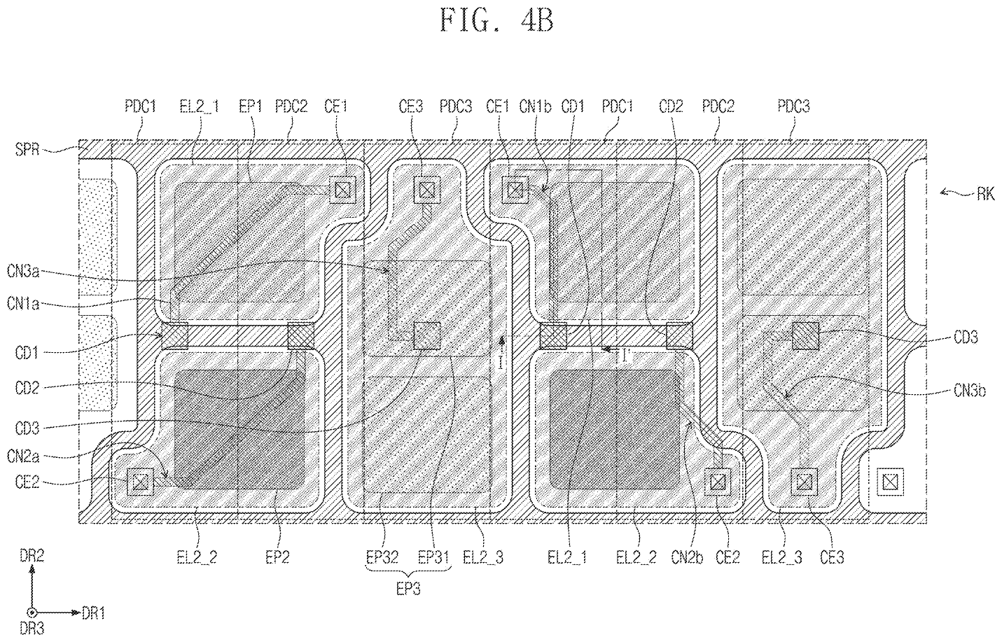

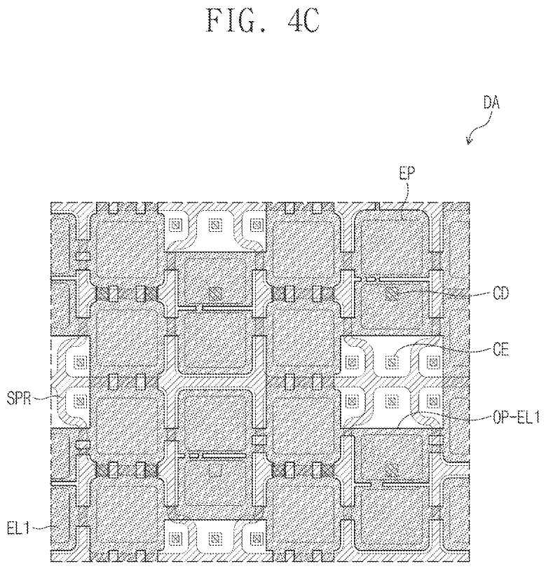

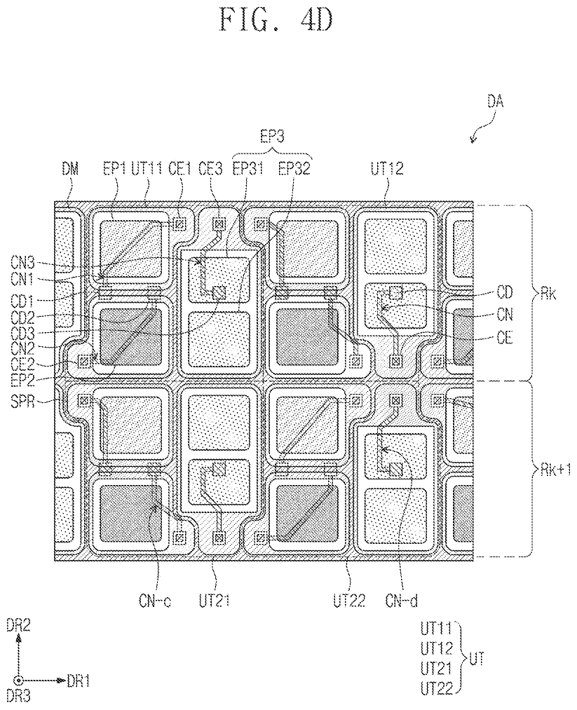

FIGS. 4A-4D are enlarged plan views of a partial area of the display panel according to one or more embodiments of the present disclosure. FIG. 4A illustrates an area in which four unit pixels UT are arranged in two rows and two columns. FIG. 4B is an enlarged view illustrating a partial area illustrated in FIG. 4A. In FIG. 4C, some components illustrated in FIG. 4A are omitted or emphasized. Hereinafter, some embodiments will first be described with reference to FIGS. 4A to 4C.

FIG. 4A illustrates unit pixels UT11, UT12, UT21, and UT22 in two rows and two columns. The unit pixels in a first row Rk include light emitting units (e.g., light emitting elements) constituting the first row first column unit pixel UT11 and the first row second column unit pixel UT12. The unit pixels in a second row Rk+1 include light emitting units (e.g., light emitting elements) constituting the second row first column unit pixel UT21 and the second row second column unit pixel UT22. FIG. 4B illustrates the unit pixels in the first row Rk. FIGS. 4A to 4C illustrate a separator SPR, a plurality of light emitting units (e.g., a plurality of light emitting elements) EP1, EP2, and EP3 arranged in an area partitioned by the separator SPR, connection wiring lines CN1, CN2, and CN3, a first electrode EL1, and second electrodes EL2_1, EL2_2, and EL2_3 from among the components of the display panel. The plurality of light emitting units EP1, EP2, and EP3 illustrated in FIGS. 4A to 4C correspond to some of the plurality of light emitting units EP illustrated in FIG. 3A.

As described above, the light emitting units EP1, EP2, and EP3 may correspond to the light emitting openings OP-PDL (e.g., see FIG. 5), which will be described in more detail below. In other words, the light emitting units EP1, EP2, and EP3 may be areas in which light beams are emitted by the above-described light emitting elements, and may correspond to a unit constituting an image displayed on the display panel DP (e.g., see FIG. 1). In more detail, the light emitting units EP1, EP2, and EP3 may correspond to an area defined by the light emitting openings OP-PDL (e.g., see FIG. 5), particularly, an area defined by a lower surface of the light emitting openings OP-PDL.

The light emitting units EP1, EP2, and EP3 may include a first light emitting unit EP1, a second light emitting unit EP2, and a third light emitting unit EP3. The first light emitting unit EP1, the second light emitting unit EP2, and the third light emitting unit EP3 may emit light beams having different colors from each other. For example, the first light emitting unit EP1 may emit a red light beam, the second light emitting unit EP2 may emit a green light beam, and the third light emitting unit EP3 may emit a blue light beam. However, the combination of the colors is not limited thereto. Further, at least two of the light emitting units EP1, EP2, and EP3 may emit light beams having the same or substantially the same color as each other. For example, all the first to third light emitting units EP1, EP2, and EP3 may emit blue light beams, or may emit white light beams.

From among the light emitting units EP1, EP2, and EP3, the third light emitting unit EP3 that displays a light beam emitted by a third light emitting element may include two sub-light emitting units EP31 and EP32 that are spaced apart from each other in the second direction DR2. However, the present disclosure is not limited thereto, and the third light emitting unit EP3 may be provided as one pattern having an integral shape, like that of the other light emitting units EP1 and EP2, and/or at least one of the other light emitting units EP1 and EP2 may include sub-light emitting units that are spaced apart from each other. However, the present disclosure is not limited to any particular embodiment.

The unit pixels in the first row Rk include the light emitting units EP1, EP2, and EP3 constituting the first row first column unit pixel UT11 and the first row second column unit pixel UT12. The unit pixels in the second row Rk+1 include the light emitting units EP1, EP2, and EP3 constituting the second row first column unit pixel UT21 and the second row second column unit pixel UT22. Some of the light emitting units in the first row Rk and some of the light emitting units in the second row Rk+1 may have symmetrical or substantially symmetrical shapes as each other. For example, the first light emitting unit EP1 and the second light emitting unit EP2 of the second row first column unit pixel UT21 and the first light emitting unit EP1 and the second light emitting unit EP2 of the first row first column unit pixel UT11 may have shapes and arrangements that are line-symmetrical to each other with respect to an axis parallel to the second direction DR2. The third light emitting unit EP3 of the second row first column unit pixel UT21 and the third light emitting unit EP3 of the first row first column unit pixel UT11 may have shapes and arrangements that are line-symmetrical to each other with respect to an axis parallel to the first direction DR1. However, the present disclosure is not limited thereto.

Hereinafter, the first row first column unit pixel UT11 will be described in more detail as a representative example. For convenience of illustration, FIG. 4B shows the plurality of second electrodes EL2_1, EL2_2, and EL2_3, a plurality of pixel driving units (e.g., a plurality of pixel driving circuits) PDC1, PDC2, and PDC3, and a plurality of connection wiring lines CN1a, CN1b, CN2a, CN2b, CN3a, and CN3b. The second electrodes EL2_1, EL2_2, and EL2_3 may be spaced apart (e.g., separated) from each other, and electrically disconnected from each other by the separator SPR. In an embodiment, one unit pixel UT may include the three light emitting units EP1, EP2, and EP3. Accordingly, the unit pixel UT may include the three second electrodes EL2_1, EL2_2, and EL2_3 (hereinafter, referred to as first to third cathodes), the three pixel driving units PDC1, PDC2, and PDC3, and the three connection wiring lines CN1a, CN2a, and CN3a or CN1b, CN2b, and CN3b. However, the present disclosure is not limited thereto, and the number and arrangement of the unit pixels UT may be variously modified as needed or desired.

The first to third pixel driving units PDC1, PDC2, and PDC3 may be electrically connected to the light emitting elements constituting the first to third light emitting units EP1, EP2, and EP3, respectively. In the present specification, the term “connected” includes a case of being physically connected by a direct contact, as well as a case of being electrically connected.

Further, as illustrated in FIG. 4B, areas in which the pixel driving units PDC1, PDC2, and PDC3 are defined on a plane (e.g., in a plan view) may correspond to units in which the transistors and capacitor elements constituting the pixel driving unit (e.g., the pixel driving circuit) PDC (e.g., see FIG. 2) for driving the light emitting element of the pixel are repeatedly arranged.

The first to third pixel driving units PDC1, PDC2, and PDC3 may be sequentially arranged along the first direction DR1. The arrangement positions of the first to third pixel driving units PDC1, PDC2, and PDC3 may be independently designed regardless of positions or shapes of the first to third light emitting units EP1, EP2, and EP3.

For example, the first to third pixel driving units PDC1, PDC2, and PDC3 may be arranged at positions different from areas partitioned and defined by the separator SPR, or in other words, positions in which the first to third cathodes EL2_1, EL2_2, and EL2_3 are arranged, or may be designed to have shapes different from shapes of the first to third cathodes EL2_1, EL2_2, and EL2_3. As another example, the first to third pixel driving units PDC1, PDC2, and PDC3 may be areas that are arranged to overlap with positions in which the first to third light emitting units EP1, EP2, and EP3 are present, partitioned, and defined by the separator SPR, for example, such as to have shapes and areas substantially the same as or similar to those of the first to third cathodes EL2_1, EL2_2, and EL2_3.

According to an embodiment, the first to third pixel driving units PDC1, PDC2, and PDC3 may have a rectangular shape as illustrated, the first to third light emitting units EP1, EP2, and EP3 may be arranged in a smaller area than and a different shape from the first to third pixel driving units PDC1, PDC2, and PDC3, and the first to third cathodes EL2_1, EL2_2, and EL2_3 may be arranged at positions overlapping with the first to third light emitting units EP1, EP2, and EP3 and in irregular shapes as illustrated.

As such, as illustrated in FIG. 4B, the first pixel driving unit PDC1 may be disposed at a position partially overlapping with the first light emitting unit EP1, the second light emitting unit EP2, and another adjacent light emitting unit(s). The second pixel driving unit PDC2 may be disposed at a position overlapping with the first light emitting unit EP1, the second light emitting unit EP2, and the third light emitting unit EP3. The third pixel driving unit PDC3 may be disposed at a position overlapping with the third light emitting unit EP3. As described above, the positions of the first to third pixel driving units PDC1, PDC2, and PDC3 may be designed in various suitable shapes and arrangements independently of the light emitting units EP1, EP2, and EP3, but the present disclosure is not limited thereto.

The connection wiring lines CN may be provided as a plurality of connection wiring lines CN, which may be spaced apart from each other. The connection wiring lines CN may electrically connect the pixel driving unit PDC (e.g., see FIG. 2A) and the light emitting element LD (e.g., see FIG. 5) to each other. In more detail, the connection wiring line CN may correspond to a node (e.g., see the fourth node N4 of FIG. 2A or the second node N2 of FIG. 2B) through which the light emitting element LD (e.g., see FIG. 5) is connected to the pixel driving unit PDC.

The connection wiring line CN may include a first connection part (e.g., a light emitting connection part) CE and a second connection part (e.g., a driving connection part) CD. The light emitting connection part CE may be provided on one side of the connection wiring line CN, and the driving connection part CD may be provided on the other side of the connection wiring line CN.

The driving connection part CD may be a part of the connection wiring line CN that is connected to the pixel driving unit PDC. In an embodiment, the driving connection part CD may be connected to one electrode of a transistor constituting the pixel driving unit PDC. In more detail, the driving connection part CD may be connected to the drain of the sixth transistor T6 illustrated in FIG. 2A, or the drain of the first transistor T1 illustrated in FIG. 2B. Accordingly, the position of the driving connection part CD may correspond to a position of the transistor (e.g., see the transistor TR in FIG. 5) of the pixel driving unit PDC, which may be physically connected to the connection wiring line CN. The light emitting connection part CE may be a part of the connection wiring line CN that is connected to the light emitting element. In an embodiment, the light emitting connection part CE may be connected to a second electrode EL2 (e.g., see FIG. 5), or in other words, the cathode of the light emitting element.

The unit pixel UT may include the first to third connection wiring lines CN1, CN2, and CN3. The first connection wiring line CN1 may connect the light emitting element forming the first light emitting unit EP1 and the first pixel driving unit PDC1 to each other. The second connection wiring line CN2 may connect the light emitting element forming the second light emitting unit EP2 and the second pixel driving unit PDC2 to each other. The third connection wiring line CN3 may connect the light emitting element forming the third light emitting unit EP3 and the third pixel driving unit PDC3 to each other.

In more detail, the first to third connection wiring lines CN1, CN2, and CN3 may connect the first to third cathodes EL2_1, EL2_2, and EL2_3 to the first to third pixel driving units PDC1, PDC2, and PDC3, respectively. The first connection wiring line CN1 may include a first driving connection part CD1 connected to the first pixel driving unit PDC1, and a first light emitting connection part CE1 connected to the first cathode EL2_1. The second connection wiring line CN2 may include a second driving connection part CD2 connected to the second pixel driving unit PDC2, and a second light emitting connection part CE2 connected to the second cathode EL2_2. The third connection wiring line CN3 may include a third driving connection part CD3 connected to the third pixel driving unit PDC3, and a third light emitting connection part CE3 connected to the third cathode EL2_3.

The first to third driving connection parts CD1, CD2, and CD3 may be aligned in the first direction DR1. As described above, the first to third driving connection parts CD1, CD2, and CD3 may correspond to positions of connection transistors constituting the first to third pixel driving units PDC1, PDC2, and PDC3. The connection transistor may be a transistor including, as one electrode, the connection node through which the pixel driving unit and the light emitting element are connected to each other in one pixel, and for example, may correspond to the sixth transistor T6 of FIG. 2A or the first transistor T1 of FIG. 2B. According to one or more embodiments of the present disclosure, regardless of the shape or size of the light emitting unit and the color of the light beam, the shape, the position, and the arrangement of the pixel driving unit of all of the pixels may be simply configured and designed.

In an embodiment, the first to third light emitting connection parts CE1, CE2, and CE3 may be arranged at positions that do not overlap with the light emitting units EP1, EP2, and EP3 on a plane (e.g., in a plan view). As will be described in more detail below, the light emitting connection part CE of the connection wiring line CN is a part to which the light emitting element LD (e.g., see FIG. 5) is connected, and is a part in which a tip portion TP is defined, and thus, may be provided at a position that does not overlap with the light emitting opening OP-PDL. In other words, the light emitting connection parts CE1, CE2, and CE3 may be arranged at positions spaced apart from the light emitting units EP1, EP2, and EP3 in the cathodes EL2_1, EL2_2, and EL2_3, and the cathodes EL2_1, EL2_2, and EL2_3 may include partial areas protruding from the light emitting units EP1, EP2, and EP3 on a plane (e.g., in a plan view), so that the cathodes EL2_1, EL2_2, and EL2_3 are connected to the connection wiring lines CN1, CN2, and CN3 in positions in which the light emitting connection parts CE1, CE2, and CE3 are arranged.

For example, the first cathode EL2_1 may include a protrusion part having a shape protruding from the first light emitting unit EP1 at a position that does not overlap with the first light emitting unit EP1, so that the first cathode EL2_1 is connected to the first connection wiring line CN1 at a position in which the first light emitting connection part CE1 is disposed, and the first light emitting connection part CE1 may be provided in the protrusion part.

Further, a part of the first pixel driving unit PDC1, particularly, the first driving connection part CD1 at a position in which the first connection wiring line CN1 is connected to the transistor TR (e.g., see FIG. 5), may be defined at a position that does not overlap with the first light emitting unit EP1 on a plane (e.g., in a plan view). According to an embodiment, the first connection wiring line CN1 may be disposed in the first light emitting unit EP1, and thus, the first cathode EL2_1 and the first pixel driving unit PDC1 that are at least partially spaced apart from each other may be easily connected to each other.

A part of the third pixel driving unit PDC3, particularly, the third driving connection part CD3 at a position in which the third connection wiring line CN3 is connected to the transistor TR, may be defined at a position that does not overlap with the third light emitting connection part CE3 on a plane (e.g., in a plan view), and may be disposed at a position overlapping with the third light emitting unit EP3. According to an embodiment, because the third cathode EL2_3 and the pixel driving unit PDC3 are connected to each other through the third connection wiring line CN3, in designing the pixel driving unit PDC3, restrictions on the position or shape of the third light emitting unit EP3 may be reduced, and thus, a degree of design freedom may be improved.

Referring back to FIG. 4A, the light emitting units in the second row Rk+1 may be light emitting units having a shape and arrangement in which the first row unit pixels UT11 and UT12 are line-symmetrical to each other with respect to an axis parallel to the first direction DR1 or the second direction DR2. In this case, due to characteristics of the shape and arrangement of the first row unit pixels UT11 and UT12, the second row unit pixels UT21 and UT22 may include the light emitting units in which the light emitting units in the first row unit pixels UT11 and UT12 are shifted or substantially shifted in the first direction DR1 or the second direction DR2. In other words, the second row first column unit pixel UT21 may be a unit pixel having the same shape as that of the first row second column unit pixel UT12, and the second row second column unit pixel UT22 may be a unit pixel having the same shape as that of the first row first column unit pixel UT11.

Accordingly, the shape and arrangement of connection wiring lines CN-c arranged in the second row first column unit pixel UT21 may be the same as those of connection wiring lines CN1b, CN2b, and CN3b arranged in the first row second column unit pixel UT12. Similarly, the shape and arrangement of connection wiring lines CN-d arranged in the second row second column unit pixel UT22 may be the same as those of the connection wiring lines CN1a, CN2a, and CN3a arranged in the first row first column unit pixel UT11.

Referring to FIG. 4C, the first electrode EL1 (hereinafter, referred to as an anode) of the light emitting element according to an embodiment of the present disclosure may be commonly provided in the plurality of light emitting units EP1, EP2, and EP3. In other words, the anode EL1 may be formed as a single layer integral with the entire or substantially the entire display area DA, and accordingly, a layer of the anode EL1 may be disposed to overlap with the separator SPR. As another example, the anodes EL1 of the light emitting elements may be formed as independent conductive patterns that are spaced apart from each other, and may be electrically connected to each other through another conductive layer, and accordingly, the patterns of the anodes EL1 may be arranged so as not to overlap with the separator SPR.

As described above, the first power voltage VDD (e.g., see FIG. 2A) may be applied to the anode EL1, and a common voltage may be applied to all the light emitting units. The anode EL1 may be connected to the first power line VDL (e.g., see FIG. 2A) that provides the first power voltage VDD in the peripheral area NDA, or may connected to the first power line VDL in the display area DA, but the present disclosure is not limited thereto.

A plurality of openings may be defined in the anode EL1 according to an embodiment, and the openings may pass through (e.g., may penetrate) the layer of the anode EL1. The openings in the layer of the anode EL1 may be arranged at positions that do not overlap with the light emitting units EP, and may generally be defined at positions that overlap with the separator SPR. The openings may facilitate a discharge of gas that may be generated from an organic layer disposed under the anode EL1, for example, such as gas generated from a sixth insulating layer 60 (e.g., see FIG. 5). Accordingly, in a process of manufacturing the display panel, the gas in the organic layer disposed under the light emitting element may be sufficiently discharged, and after the manufacturing, the gas discharged from the organic layer may be reduced, and thus, a degradation speed of the light emitting element may be reduced.

According to one or more embodiments of the present disclosure, because the connection wiring line may be included between the light emitting element and the pixel driving unit, even when only the shape of the cathode is changed without changing the arrangement or shape of the light emitting units, the light emitting element may be easily connected to the pixel driving unit. Accordingly, the degree of freedom for the arrangement of the pixel driving unit may be improved, and an area or resolution of the light emitting unit of the display panel may be easily increased.

FIG. 4D illustrates an area in which a total of four unit pixels UT in two rows and two columns are arranged. In FIG. 4D, the same reference numerals and symbols denote the same or substantially the same elements as those described above, and thus, redundant description may not be repeated.

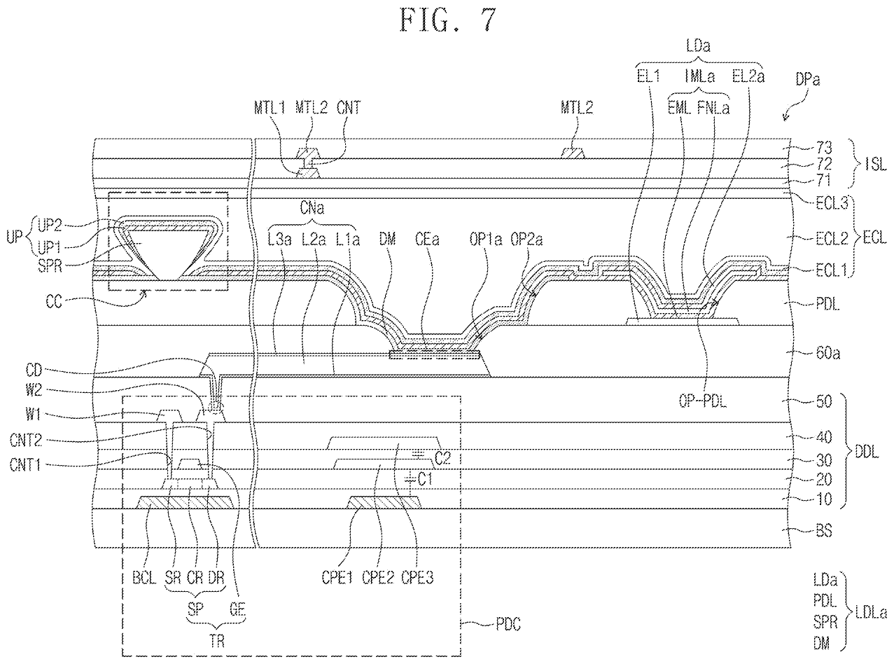

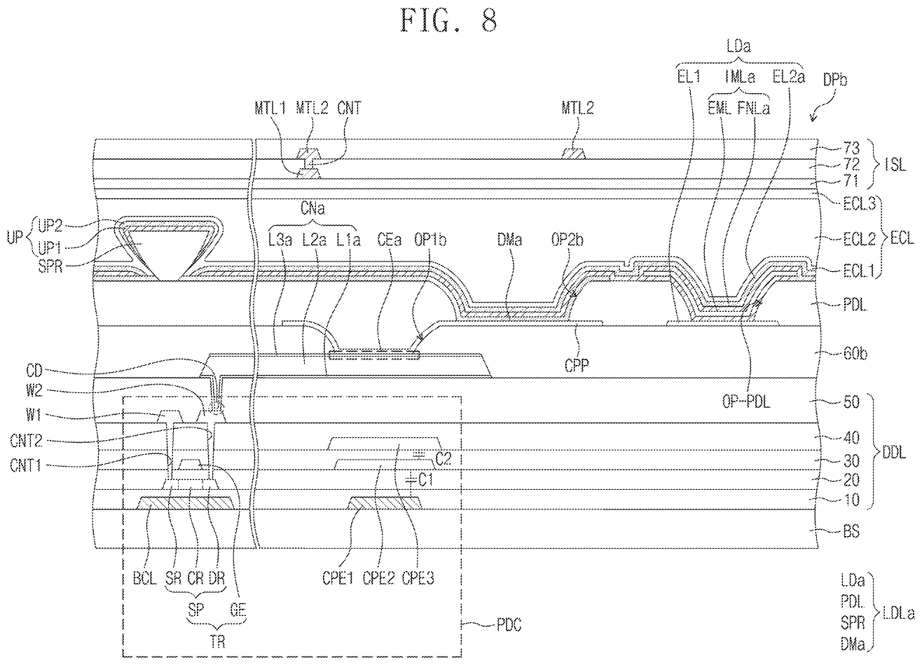

Referring to FIG. 4D, in some embodiments, the display device DD (e.g., see FIG. 1) may further include a metal layer DM electrically connected to the connection wiring line CN. The metal layer DM may be electrically connected to the light emitting connection part CE of the connection wiring line CN. For example, the metal layer DM may be connected to the connection wiring line CN through a direct contact, or the metal layer DM may be indirectly connected to the connection wiring line CN through a capping pattern CPP (e.g., see FIG. 8). Because the display device DD further includes the metal layer DM, a contact area in which a second electrode EL2a (e.g., see FIG. 7) of a light emitting element LDa is connected to the connection wiring line CN may be widened. Thus, a connection reliability between the light emitting element LDa and the connection wiring line CN may be improved. This will be described in more detail below with reference to FIGS. 7 and 8.

The metal layer DM may be formed to surround (e.g., around a periphery of) the separator SPR on a plane (e.g., in a plan view). The metal layer DM may be formed in contact with a side surface of the separator SPR. After the metal layer DM is deposited and a portion of the metal layer DM is etched, the separator SPR may be formed to overlap with the etched portion that has been removed.

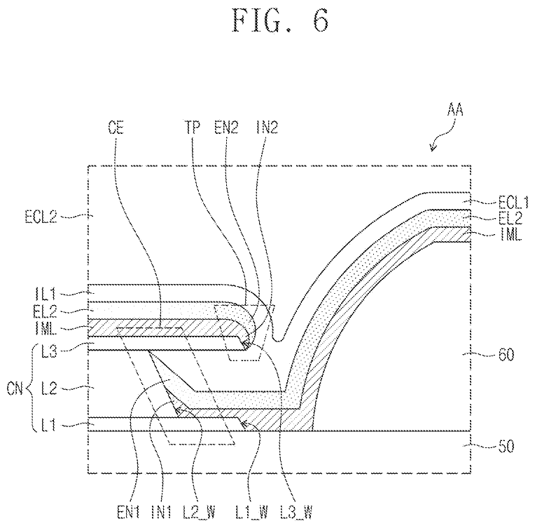

FIG. 5 is a cross-sectional view of the display panel DP according to an embodiment of the present disclosure. FIG. 5 is a cross-sectional view illustrating a part corresponding to the line I-I′ of FIG. 4B. FIG. 6 is an enlarged cross-sectional view of a partial area of the display panel according to an embodiment of the present disclosure. FIG. 6 is an enlarged cross-sectional view of the part AA of FIG. 5.

Referring to FIG. 5, the display panel DP according to an embodiment may include a display layer DPL that displays an image, and a detection layer ISL disposed on the display layer DPL. The display layer DPL may include a base layer BS, a driving element layer DDL, the sixth insulating layer 60, a light emitting element layer LDL, and an encapsulation layer ECL.

The driving element layer DDL may include a plurality of insulating layers 10, 20, 30, 40, and 50 arranged on the base layer BS, and a plurality of conductive patterns and a plurality of semiconductor patterns arranged between the insulating layers 10, 20, 30, 40, and 50. The conductive patterns and the semiconductor patterns may be arranged between the insulating layers to constitute the pixel driving unit PDC. For convenience of illustration, FIG. 5 shows a cross section of one of the areas in which one light emitting unit is disposed.

The base layer BS may be a member that provides a base surface on which the pixel driving unit PDC is disposed. The base layer BS may be a rigid substrate, or a flexible substrate that may be bent, folded, and/or rolled. The base layer BS may be a glass substrate, a metal substrate, a polymer substrate, or the like. However, the present disclosure is not limited thereto, and the base layer BS may be an inorganic layer, an organic layer, or a composite material layer.

The base layer BS may have a multi-layered structure. The base layer BS may include a first polymer resin layer, a silicon oxide SiOₓ layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

The polymer resin layer may include a polyimide-based resin. The polymer resin layer may include at least one of an acrylate-based resin, a methacrylate-based resin, a polyisoprene-based resin, a vinyl-based resin, an epoxy-based resin, an urethane-based resin, a cellulose-based resin, a siloxane-based resin, a polyamide-based resin, and/or a perylene-based resin. As used in the present specification, a “˜˜based” resin refers to a resin containing a functional group of “˜˜”.

The insulating layers, the conductive layers, and the semiconductor layers arranged on the base layer BS may be formed by various suitable methods, such as coating and deposition. Thereafter, through a plurality of photolithography processes, the insulating layer, the semiconductor layer, and the conductive layer may be selectively patterned, so that a hole may be formed in the insulating layer, or the semiconductor pattern, the conductive pattern, the signal line, and/or the like may be formed.

The driving element layer DDL may include the first to fifth insulating layers 10, 20, 30, 40, and 50 and the pixel driving unit PDC sequentially laminated on the base layer BS. FIG. 5 illustrates one transistor TR and the two capacitors C1 and C2 of the pixel driving unit PDC. The transistor TR may correspond to a transistor connected to the light emitting element LD through the connection wiring line CN, or in other words, a connection transistor connected to the node (e.g., the fourth node N4 in FIG. 2A or the second node N2 in FIG. 2B) corresponding to the cathode of the light emitting element LD. In more detail, the transistor TR may correspond to the sixth transistor T6 in FIG. 2A or the first transistor T1 in FIG. 2B. The other transistors constituting the pixel driving unit PDC may have the same or substantially the same structure as that of the transistor TR (hereinafter, referred to as the connection transistor) illustrated in FIG. 5. However, the present disclosure is not limited thereto, and the other transistors constituting the pixel driving unit PDC may have a structure different from that of the connection transistor TR illustrated in FIG. 5.

The first insulating layer 10 may be disposed on the base layer BS. The first insulating layer 10 may be an inorganic layer and/or an organic layer, and may have a single-layer structure or a multi-layered structure. The first insulating layer 10 may include at least one of an aluminum oxide, a titanium oxide, a silicon oxide, a silicon nitride, a silicon oxynitride, a zirconium oxide, or a hafnium oxide. In an embodiment, the first insulating layer 10 may be a single silicon oxide layer. The insulating layers, which will be described in more detail below, may be an inorganic layer and/or an organic layer, and may have a single-layer structure or a multi-layered structure. The inorganic layer may include at least one of the above-described materials, but the present disclosure is not limited thereto.

The first insulating layer 10 may cover a lower conductive layer BCL. In other words, the display panel DP may further include the lower conductive layer BCL disposed to overlap with the connection transistor TR. The lower conductive layer BCL may block an electric potential due to a polarization phenomenon of the base layer BS from affecting the connection transistor TR. Further, the lower conductive layer BCL may block a light beam input from a lower side to the connection transistor TR. At least one of an inorganic barrier layer and/or a buffer layer may be further disposed between the lower conductive layer BCL and the base layer BS.

The lower conductive layer BCL may include a reflective metal. For example, the lower conductive layer BCL may include titanium (Ti), molybdenum (Mo), an alloy containing molybdenum, aluminum (Al), an alloy containing aluminum, aluminum nitride (AlN), tungsten (W), tungsten nitride (WN), copper (Cu), or the like.

In an embodiment, the lower conductive layer BCL may be connected to a source of the connection transistor TR (or the transistor) through a source electrode pattern W1. In this case, the lower conductive layer BCL may be synchronized with the source of the transistor TR. However, the present disclosure is not limited thereto, and the lower conductive layer BCL may be connected to a gate of the transistor TR and synchronized with the gate. As another example, the lower conductive layer BCL may be connected to another electrode to independently receive a constant voltage or a pulse signal. As another example, the lower conductive layer BCL may be provided in the form of being isolated from other conductive patterns. The lower conductive layer BCL may be provided in various suitable forms and is not limited to any particular embodiment.

The connection transistor TR may be disposed on the first insulating layer 10. The connection transistor TR may include a semiconductor pattern SP and a gate electrode GE. The semiconductor pattern SP may be disposed on the first insulating layer 10. The semiconductor pattern SP may include an oxide semiconductor. For example, the oxide semiconductor may include a transparent conductive oxide TCO, such as indium tin oxide (ITO), indium zinc oxide (IZO), indium gallium zinc oxide (IGZO), zinc oxide (ZnO), or indium oxide (In₂O₃). However, the present disclosure is not limited thereto, and the semiconductor pattern SP may include amorphous silicon, a low-temperature polycrystalline silicon, or polycrystalline silicon.

The semiconductor pattern SP may include a source region SR, a drain region DR, and a channel region CR, which are distinguished from one another according to a degree of conductivity. The channel region CR may be a portion overlapping with the gate electrode GE on a plane (e.g., in a plan view). The source region SR and the drain region DR may be portions spaced apart from each other with the channel region CR interposed therebetween. When the semiconductor pattern SP is the oxide semiconductor, the source region SR and the drain region DR may be reduced regions. Accordingly, the source region SR and the drain region DR have a relatively higher reduction metal content compared to that of the channel region CR. As another example, when the semiconductor pattern SP is the polycrystalline silicon, the source region SR and the drain region DR may be regions doped at a higher concentration.

The source region SR and the drain region DR may have a relatively higher conductivity than that of the channel region CR. The source region SR may correspond to a source electrode of the connection transistor TR, and the drain region DR may correspond to a drain electrode of the connection transistor TR. As illustrated in FIG. 5, a separate source electrode pattern W1 and a separate drain electrode pattern W2 connected to the source region SR and the drain region DR, respectively, may be further provided. In more detail, the separate source electrode pattern W1 and the separate drain electrode pattern W2 may be formed integrally with one of the lines constituting the pixel driving unit PDC or PDC−1 (e.g., see FIGS. 2A and 2B), but the present disclosure is not limited thereto.

The second insulating layer 20 may commonly overlap with the plurality of pixels, and cover the semiconductor pattern SP. The second insulating layer 20 may be an inorganic layer and/or an organic layer, and may have a single-layer structure or a multi-layered structure. The second insulating layer 20 may include at least one of an aluminum oxide, a titanium oxide, a silicon oxide, a silicon nitride, a silicon oxynitride, a zirconium oxide, or a hafnium oxide. In an embodiment, the second insulating layer 20 may be a single silicon oxide layer.

The gate electrode GE may be disposed on the second insulating layer 20. The gate electrode GE may correspond to the gate of the connection transistor TR. Further, the gate electrode GE may also be disposed on the semiconductor pattern SP. However, the present disclosure is not limited thereto, and the gate electrode GE may be disposed below (e.g., under) the semiconductor pattern SP.

The gate electrode GE may include titanium (Ti), silver (Ag), molybdenum (Mo), aluminum (Al), aluminum nitride (AlN), tungsten (W), tungsten nitride (WN), copper (Cu), or a suitable alloy thereof, but the present disclosure is not particularly limited thereto.

The third insulating layer 30 may be disposed on the gate electrode GE. The third insulating layer 30 may be an inorganic layer and/or an organic layer, and may have a single-layer structure or a multi-layered structure. The fourth insulating layer 40 may include at least one of an aluminum oxide, a titanium oxide, a silicon oxide, a silicon nitride, a silicon oxynitride, a zirconium oxide, or a hafnium oxide.

A first capacitor electrode CPE1 and a second capacitor electrode CPE2 from among the plurality of conductive patterns W1, W2, CPE1, CPE2, and CPE3 constitute the first capacitor C1. The first capacitor electrode CPE1 and the second capacitor electrode CPE2 may be spaced apart from each other with the first insulating layer 10 and the second insulating layer 20 interposed therebetween.

In an embodiment of the present disclosure, the first capacitor electrode CPE1 and the lower conductive layer BCL may have an integral shape. Further, the second capacitor electrode CPE2 and the gate electrode GE may have an integral shape.

The third capacitor electrode CPE3 may be disposed on the third insulating layer 30. The third capacitor electrode CPE3 may be spaced apart from the second capacitor electrode CPE2 with the third insulating layer 30 interposed therebetween, and may overlap with the second capacitor electrode CPE2 on a plane (e.g., in a plan view). The third capacitor electrode CPE3 and the second capacitor electrode CPE2 may constitute the second capacitor C2.

The fourth insulating layer 40 may be disposed on the third insulating layer 30 and/or the third capacitor electrode CPE3. The fourth insulating layer 40 may be an inorganic layer and/or an organic layer, and may have a single-layer structure or a multi-layered structure. The fourth insulating layer 40 may include at least one of an aluminum oxide, a titanium oxide, a silicon oxide, a silicon nitride, a silicon oxynitride, a zirconium oxide, or a hafnium oxide.

The source electrode pattern W1 and the drain electrode pattern W2 may be arranged on the fourth insulating layer 40. The source electrode pattern W1 may be connected to the source region SR of the connection transistor TR through a first contact hole CNT1, and the source electrode pattern W1 and the source region SR of the semiconductor pattern SP may function as the source of the connection transistor TR. The drain electrode pattern W2 may be connected to the drain region DR of the connection transistor TR through a second contact hole CNT2, and the drain electrode pattern W2 and the drain region DR of the semiconductor pattern SP may function as a drain of the connection transistor TR. The fifth insulating layer 50 may be disposed on the source electrode pattern W1 and the drain electrode pattern W2.

The connection wiring line CN may be disposed on the fifth insulating layer 50. The connection wiring line CN may electrically connect the pixel driving unit PDC and the light emitting element LD to each other. In other words, the connection wiring line CN may electrically connect the connection transistor TR and the light emitting element LD to each other. The connection wiring line CN may be a connection node that connects the pixel driving unit PDC and the light emitting element LD to each other. In other words, the connection wiring line CN may correspond to the fourth node N4 illustrated in FIG. 2A, or may correspond to the second node N2 illustrated in FIG. 2B. However, the present disclosure is not limited thereto, and the connection wiring line CN may be defined as a connection node with various suitable elements from among the elements constituting the pixel driving unit PDC according to the design of the pixel driving unit PDC, as long as the connection wiring line CN is connected to the light emitting element LD.

The sixth insulating layer 60 may be disposed on the connection wiring line CN. The sixth insulating layer 60 may be disposed on the fifth insulating layer 50 to cover the connection wiring line CN. The fifth insulating layer 50 and the sixth insulating layer 60 may be organic layers. For example, each of the fifth insulating layer 50 and the sixth insulating layer 60 may include a general purpose polymer, such as benzocyclobutene (BCB), polyimide, hexamethyldisiloxane (HMDSO), polymethylmethacrylate (PMMA), and/or polystyrene (PS), a polymer derivative having a phenolic group, an acryl-based polymer, an imide-based polymer, an arylether-based polymer, an amide-based polymer, a fluorine-based polymer, a p-xylene-based polymer, a vinyl alcohol-based polymer, and/or a suitable blend thereof.

An opening through which at least a portion of the connection wiring line CN is exposed may be provided in the sixth insulating layer 60. The connection wiring line CN may be electrically connected to the light emitting element LD through the portion exposed thereof from the sixth insulating layer 60. In other words, the connection wiring line CN may electrically connect the connection transistor TR and the light emitting element LD to each other. A more detailed description thereof will be provided below. In the display panel DP according to an embodiment of the present disclosure, the sixth insulating layer 60 may be omitted as needed or desired, or may be provided as a plurality of sixth insulating layers 60, and the present disclosure is not limited to any particular embodiment.

The light emitting element layer LDL may be disposed on the sixth insulating layer 60. The light emitting element layer LDL may include a pixel definition film PDL, the light emitting element LD, and the separator SPR. The pixel definition film PDL may be an organic layer. For example, the pixel definition film PDL may include a general purpose polymer, such as BCB, polyimide, HMDSO, PMMA, and/or PS, a polymer derivative having a phenolic group, an acryl-based polymer, an imide-based polymer, an arylether-based polymer, an amide-based polymer, a fluorine-based polymer, a p-xylene-based polymer, a vinyl alcohol-based polymer, and/or a suitable blend thereof.

In an embodiment, the pixel definition film PDL may have a property of absorbing a light beam, and may have, for example, a black color. In other words, the pixel definition film PDL may include a black coloring agent. The black coloring agent may include a black dye and a black pigment. The black coloring agent may include carbon black, a metal such as chromium, or an oxide thereof. The pixel definition film PDL may correspond to a light blocking pattern having light blocking characteristics.

The opening OP-PDL (hereinafter, referred to as a light emitting opening), through which at least a portion of the first electrode EL1 is exposed, may be defined in the pixel definition film PDL. In other words, the light emitting opening OP-PDL may overlap with a portion of the first electrode EL1. The light emitting opening OP-PDL may be provided in a plurality of light emitting openings OP-PDL, which may be arranged to correspond to the light emitting elements, respectively. All components of the light emitting element LD may be arranged to overlap with the light emitting opening OP-PDL, and the light emitting opening OP-PDL may be an area (hereinafter, a light emitting area) on which a light beam emitted by the light emitting element LD is displayed or substantially displayed. Accordingly, the shape of the light emitting unit EP1, EP2, or EP3 (e.g., see FIG. 4A) may correspond to or substantially correspond to the shape of the light emitting opening OP-PDL on a plane (e.g., in a plan view).

The light emitting element LD may include the first electrode EL1, an intermediate layer IML, and the second electrode EL2. The first electrode EL1 may be a semi-transmissive, transmissive, or reflective electrode. According to an embodiment of the present disclosure, the first electrode EL1 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a suitable compound thereof, and a transparent or translucent electrode layer formed on the reflective layer. The transparent or translucent electrode layer may include at least one selected from the group consisting of indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the first electrode EL1 may include a laminated structure of ITO/Ag/ITO.

In an embodiment, the first electrode EL1 may be the anode of the light emitting element LD. In other words, the first electrode EL1 may be connected to the first power line VDL (e.g., see FIG. 2A), and the first power voltage VDD may be applied to the first electrode EL1. The first electrode EL1 may be connected to the first power line VDL inside the display area DA (e.g., see FIG. 3A or 3B), or may be connected to the first power line VDL in the peripheral area NDA. In the latter case, the first power line VDL may be disposed in the peripheral area NDA (e.g., see FIG. 3A or 3B), and the first electrode EL1 may have a shape extending up to the peripheral area NDA.

In the cross-sectional view of FIG. 5, it is illustrated that the first electrode EL1 overlaps with the light emitting opening OP-PDL, and does not overlap with the separator SPR. However, as illustrated in FIG. 4C, the first electrodes EL1 of the light emitting elements may have an integral shape, and may have a mesh or lattice shape in which openings are defined in a partial area thereof. In other words, when the same first power voltage VDD may be applied to the first electrode EL1 of each of the plurality of light emitting elements, the shape of the first electrode EL1 may be variously provided, and the present disclosure is not limited to any particular embodiment.

The intermediate layer IML may be disposed between the first electrode EL1 and the second electrode EL2. The intermediate layer IML may include a light emitting layer EML and a functional layer FNL. The light emitting element LD may include the intermediate layer IML having various suitable structures, and the present disclosure is not limited to any particular embodiment. For example, the functional layer FNL may be provided as a plurality of layers or as two or more layers spaced apart from each other with the light emitting layer EML interposed therebetween. As another example, in an embodiment, the functional layer FNL may be omitted as needed or desired.

The light emitting layer EML may include an organic light emitting material. The light emitting layer EML may include an inorganic light emitting material, or may be provided as a mixed layer of the organic light emitting material and the inorganic light emitting material. In an embodiment, the light emitting layer EML included in each of the adjacent light emitting units EP (e.g., see FIG. 3A) may include light emitting materials for displaying different colors from each other. For example, the light emitting layer EML included in each of the light emitting units EP may provide any one of a blue light beam, a red light beam, and a green light beam. However, the present disclosure is not limited thereto, and all the light emitting layers EML arranged in the light emitting units EP may include a light emitting material for displaying the same or substantially the same color as each other. In this case, the light emitting layers EML may provide a blue light beam or a white light beam. Further, in FIG. 5, an embodiment in which the light emitting layer EML and the functional layer FNL have different shapes from each other is illustrated. However, the present disclosure is not limited thereto, and the light emitting layer EML and the functional layer FNL may be arranged in the same or substantially the same shape as each other on a plane (e.g., in a plan view).

The functional layer FNL may be disposed between the first electrode EL1 and the second electrode EL2. In more detail, the functional layer FNL may be disposed between the first electrode EL1 and the light emitting layer EML, or may be disposed between the second electrode EL2 and the light emitting layer EML. As another example, the functional layer FNL may be disposed both between the first electrode EL1 and the light emitting layer EML and between the second electrode EL2 and the light emitting layer EML. In an embodiment, the light emitting layer EML may be inserted into the functional layer FNL. However, the present disclosure is not limited thereto, and the functional layer FNL may include a layer disposed between the light emitting layer EML and the first electrode EL1 and/or a layer disposed between the light emitting layer EML and the second electrode EL2 to be provided as a plurality of functional layers FNL.

The functional layer FNL may control movement of charges between the first electrode EL1 and the second electrode EL2. The functional layer FNL may include a hole injection/transport material and/or an electron injection/transport material. The functional layer FNL may include at least one of an electron blocking layer, a hole transporting layer, a hole injecting layer, a hole blocking layer, an electron transporting layer, an electron injecting layer, and/or a charge generating layer.

The second electrode EL2 may be one of the second electrodes EL2_1, EL2_2, and EL2_3 illustrated in FIGS. 4A to 4C. For example, the second electrode EL2 may be the first cathode EL2_1 (e.g., see FIG. 4B). The second electrode EL2 may be disposed on the intermediate layer IML. As described above, the second electrode EL2 may be connected to the connection wiring line CN, and may be electrically connected to the pixel driving unit PDC. In other words, the second electrode EL2 may be electrically connected to the connection transistor TR through the connection wiring line CN.

As described above, the connection wiring line CN may include the driving connection part CD and the light emitting connection part CE. The driving connection part CD may be a part of the connection wiring line CN that is connected to the pixel driving unit PDC, and a part connected to or substantially connected to the connection transistor TR. In an embodiment, the driving connection part CD may be electrically connected to the drain region DR of the semiconductor pattern SP through the drain electrode pattern W2, while passing through (e.g., penetrating) the fifth insulating layer 50. The light emitting connection part CE may be a part of the connection wiring line CN that is connected to the light emitting element LD. The light emitting connection part CE may be a part that is defined in an area exposed from the sixth insulating layer 60, and to which the second electrode EL2 is connected. In this case, the tip portion TP may be defined in the light emitting connection part CE.

The light emitting connection part CE of the connection wiring line CN will be now be described in more detail with reference to FIGS. 5 and 6 together. Referring to FIGS. 5 and 6, the connection wiring line CN may have a three-layered structure. In more detail, the connection wiring line CN may include a first layer L1, a second layer L2, and a third layer L3 sequentially laminated in a third direction DR3 (e.g., see FIG. 4B). The second layer L2 may include a material that is different from that of the first layer L1. Further, the second layer L2 may include a material that is different from that of the third layer L3. The second layer L2 may have a relatively larger thickness than that of the first layer L1. Further, the second layer L2 may have a relatively larger thickness than that of the third layer L3. The second layer L2 may include a material having a high conductivity. In an embodiment, the second layer L2 may include aluminum (Al).

The first layer L1 may include a material having a lower etching rate than that of the second layer L2. In other words, the first layer L1 and the second layer L2 may be formed of materials having a high etching selectivity. In an embodiment, the first layer L1 may include titanium (Ti), and the second layer L2 may include aluminum (Al). In this case, a side surface L1_W of the first layer L1 may be defined outside a side surface L2_W of the second layer L2. In other words, the light emitting connection part CE of the connection wiring line CN may have a shape in which the side surface L1_W of the first layer L1 protrudes outward from the side surface L2_W of the second layer L2. In other words, the light emitting connection part CE of the connection wiring line CN may have a shape in which the side surface L2_W of the second layer L2 is recessed inward from the side surface L1_W of the first layer L1.

Further, the third layer L3 may include a material having a lower etching rate than that of the second layer L2. In other words, the third layer L3 and the second layer L2 may be formed of materials having a high etching selectivity. In an embodiment, the third layer L3 may include titanium (Ti), and the second layer L2 may include aluminum (Al). In this case, a side surface L3_W of the third layer L3 may be defined outside the side surface L2_W of the second layer L2. In other words, the light emitting connection part CE of the connection wiring line CN may have a shape in which the side surface L3_W of the third layer L3 protrudes outward from the side surface L2_W of the second layer L2. In other words, the light emitting connection part CE of the connection wiring line CN may have an undercut shape or an overhang structure, and the tip portion TP of the light emitting connection part CE may be defined by a portion of the third layer L3 that protrudes from the second layer L2.

The sixth insulating layer 60 and the pixel definition film PDL may expose at least a portion of the tip portion TP and at least a portion of the side surface L2_W of the second layer L2. In more detail, a first opening OP1 through which one side of the connection wiring line CN is exposed may be defined in the sixth insulating layer 60, and a second opening OP2 overlapping with the first opening OP1 may be defined in the pixel definition film PDL. A planar area of the second opening OP2 may be greater than a planar area of the first opening OP1. However, the present disclosure is not limited thereto, and the planar area of the second opening OP2 may be smaller than or equal to the planar area of the first opening OP1, as long as at least a portion of the tip portion TP and at least a portion of the side surface L2_W of the second layer L2 is exposed.

The intermediate layer IML may be disposed on the pixel definition film PDL. The intermediate layer IML may also be disposed on a partial area of the sixth insulating layer 60, which is exposed by the second opening OP2 of the pixel definition film PDL. Further, the intermediate layer IML may also be disposed on a partial area of the connection wiring line CN, which is exposed by the first opening OP1 of the sixth insulating layer 60. As illustrated in FIG. 6, the intermediate layer IML may include one end IN1 disposed along an upper surface of the fifth insulating layer 50, and another end IN2 disposed along an upper surface of the connection wiring line CN and the tip portion TP. In other words, when viewed on a cross section, the intermediate layer IML may have a shape that is partially disconnected with respect to the tip portion TP in an area in which the light emitting connection part CE is defined. However, when viewed on a plane (e.g., in a plan view), the intermediate layer IML may have an integral shape connected as a whole within an area (e.g., see FIG. 4C) defined as a closed line by the separator SPR.

The second electrode EL2 may be disposed on the intermediate layer IML. The second electrode EL2 may also be disposed on a partial area of the sixth insulating layer 60, which is exposed by the second opening OP2 of the pixel definition film PDL. Further, the second electrode EL2 may also be disposed on the partial area of the connection wiring line CN, which is exposed by the first opening OP1 of the sixth insulating layer 60. As illustrated in FIG. 6, the second electrode EL2 may include one end EN1 disposed along the upper surface of the fifth insulating layer 50, and another end EN2 disposed along the upper surface of the connection wiring line CN and the tip portion TP. In other words, when viewed on a cross section, the second electrode EL2 may have a shape that is partially disconnected with respect to the tip portion TP in the area in which the light emitting connection part CE is defined. However, when viewed on a plane (e.g., in a plan view), the second electrode EL2 may have an integral shape connected as a whole within the area (e.g., see FIG. 4C) defined as the closed line by the separator SPR.

The one end EN1 of the second electrode EL2 may be disposed along a side surface of the second layer L2, and may be in contact with the side surface L2_W of the second layer L2. In more detail, the second electrode EL2 may be formed to be in contact with the side surface L2_W of the second layer L2 exposed from the intermediate layer IML by the tip portion TP through a difference between deposition angles of the second electrode EL2 and the intermediate layer IML. In other words, the second electrode EL2 may be connected to the connection wiring line CN without a separate patterning process for the intermediate layer IML, and accordingly, the light emitting element LD may be electrically connected to the pixel driving unit PDC through the connection wiring line CN.

Further, in an embodiment, it is illustrated that the other end IN2 of the intermediate layer IML and the other end EN2 of the second electrode EL2 cover the side surface L3_W of the third layer L3. However, the present disclosure is not limited thereto, and at least a portion of the side surface L3_W of the third layer L3 may be exposed from the other end IN2 of the intermediate layer IML and/or the other end EN2 of the second electrode EL2.

As described above, the display panel DP may include the separator SPR. The separator SPR may be disposed on the pixel definition film PDL. In an embodiment, the second electrode EL2 and the intermediate layer IML may be formed by commonly depositing the plurality of pixels through an open mask. In this case, the second electrode EL2 and the intermediate layer IML may be divided by the separator SPR. As described above, the separator SPR may have a closed line shape for each light emitting unit, and accordingly, the second electrode EL2 and the intermediate layer IML may have a divided shape in each light emitting unit. In other words, the second electrode EL2 and the intermediate layer IML may be electrically independent for each adjacent pixel.

The separator SPR may include an insulating material, and in more detail, may include an organic insulating material. The separator SPR may include an inorganic insulating material, may include a multi-layered structure of the organic insulating material and the inorganic insulating material, and may include a conductive material according to an embodiment. In other words, as long as the second electrode EL2 may be electrically disconnected for each pixel, the kind of material of the separator SPR is not particularly limited.

A dummy layer UP may be disposed on the separator SPR. The dummy layer UP may include a first dummy layer UP1 disposed on the separator SPR, and a second dummy layer UP2 disposed on the first dummy layer UP1. The first dummy layer UP1 may be formed through the same process as that of the intermediate layer IML, and may include the same material as that of the intermediate layer IML. The second dummy layer UP2 may be formed through the same process as that of the second electrode EL2, and may include the same material as that of the second electrode EL2. In other words, the first dummy layer UP1 and the second dummy layer UP2 may be formed concurrently or substantially simultaneously while the intermediate layer IML and the second electrode EL2 are formed. In an embodiment, the display panel DP may not include the dummy layer UP.

Referring back to FIG. 5, the encapsulation layer ECL may be disposed on the light emitting element layer LDL. The encapsulation layer ECL may cover the light emitting element LD, and may cover the separator SPR. The encapsulation layer ECL may include a first encapsulation layer ECL1, a second encapsulation layer ECL2, and a third encapsulation layer ECL3 that are sequentially laminated. In other words, the second encapsulation layer ECL2 may be disposed on the first encapsulation layer ECL1, and the third encapsulation layer ECL3 may be disposed on the second encapsulation layer ECL2. The first encapsulation layer ECL1 may include an inorganic material and an organic material, and the second encapsulation layer ECL2 may include an organic material. The third encapsulation layer ECL3 may include an inorganic material. However, the present disclosure is not limited thereto, and the encapsulation layer ECL may further include a plurality of inorganic layers and a plurality of organic layers.

The inorganic layers including inorganic materials may protect the light emitting element LD from moisture and oxygen from outside the display panel DP, and the organic layers including organic materials may protect the light emitting element LD from foreign substances, such as particles, that may be remaining in a process of forming the inorganic layer formed under the organic layers.

The detection layer ISL may detect an external input. In an embodiment, the detection layer ISL may be formed on the encapsulation layer ECL through a subsequent process. In this case, it may be expressed that the detection layer ISL is directly disposed on the encapsulation layer ECL. The direct disposition may mean that there is no component between the detection layer ISL and the encapsulation layer ECL. In other words, a separate adhesive member may not be disposed between the detection layer ISL and the encapsulation layer ECL. However, the present disclosure is not limited thereto, and in the display panel DP according to an embodiment of the present disclosure, the detection layer ISL may be separately formed, and then, may be coupled to the display layer DPL through the adhesive member.

The detection layer ISL may include a plurality of conductive layers and a plurality of insulating layers. The plurality of conductive layers may include a first detection conductive layer MTL1 and a second detection conductive layer MTL2. The plurality of insulating layers may include first to third detection insulating layers 71, 72, and 73. However, the present disclosure is not limited thereto, and the numbers of the conductive layers and the insulating layers are not limited to those illustrated.

The first to third detection insulating layers 71, 72, and 73 may have a single-layer structure, or a multi-layered structure in which multiple layers are laminated in the third direction DR3. The first to third detection insulating layers 71, 72, and 73 may include an inorganic film. The inorganic film may include at least one of an aluminum oxide, a titanium oxide, a silicon oxide, a silicon nitride, a silicon oxynitride, a zirconium oxide, or a hafnium oxide. The first to third detection insulating layers 71, 72, and 73 may include an organic film. The organic film may include at least one of an acrylate-based resin, a methacrylate-based resin, a polyisoprene-based resin, a vinyl-based resin, an epoxy-based resin, an urethane-based resin, a cellulose-based resin, a siloxane-based resin, a polyimide-based resin, a polyamide-based resin, and/or a perylene-based resin.

The first detection conductive layer MTL1 may be disposed between the first detection insulating layer 71 and the second detection insulating layer 72. The second detection conductive layer MTL2 may be disposed between the second detection insulating layer 72 and the third detection insulating layer 73. A portion of the second detection conductive layer MTL2 may be connected to the first detection conductive layer MTL1 through a contact hole CNT formed in the second detection insulating layer 72. The first detection conductive layer MTL1 and the second detection conductive layer MTL2 may have a single-layer structure, or a multi-layered structure in which multiple layers are laminated in the third direction DR3.

The detection conductive layer having the single-layer structure may include a metal layer or a transparent conductive layer. The metal layer may include molybdenum, silver, titanium, copper, aluminum, or a suitable alloy thereof. The transparent conductive layer may include a transparent conductive oxide, such as indium tin oxide (ITO), indium zinc oxide (IZO), zinc oxide (ZnO), or indium zinc tin oxide (IZTO). As another example, the transparent conductive layer may include a conductive polymer such as PEDOT, a metal nanowire, graphene, or the like.

The detection conductive layer having the multi-layered structure may include a plurality of metal layers. For example, the metal layers may have a three-layered structure of titanium (Ti)/aluminum (Al)/titanium (Ti). As another example, the detection conductive layer having the multi-layered structure may include at least one metal layer and at least one transparent conductive layer.

The first detection conductive layer MTL1 and the second detection conductive layer MTL2 may constitute a sensor that detects an external input in the detection layer ISL. The sensor may be driven in a capacitive method, and may be driven in any one of a mutual capacitive method and/or a self-capacitive method. However, the present disclosure is not limited thereto, and the sensor may be driven by a resistive film method, an ultrasonic method, or an infrared method, in addition to the capacitive method.

The first detection conductive layer MTL1 and the second detection conductive layer MTL2 may include a transparent conductive oxide, or may have a shape of a metal mesh formed of an opaque conductive material. The first detection conductive layer MTL1 and the second detection conductive layer MTL2 may have various suitable materials and various suitable shapes, as long as the visibility of the image displayed by the display panel DP is not degraded, but the present disclosure is not limited to any particular embodiment.

FIG. 7 is a cross-sectional view of a display panel DPa according to an embodiment of the present disclosure. In the display panel DPa of FIG. 7, a connection wiring line CNa having a different shape from that of the connection wiring line CN of the display panel DP of FIG. 5, and the metal layer DM may be additionally illustrated. In FIG. 7, the same or substantially the same elements as those described above with reference to FIGS. 4D and 5 may be denoted with the same reference numerals and symbols, and thus, redundant description thereof may not be repeated.

Referring to FIG. 7, the connection wiring line CNa may be disposed on the fifth insulating layer 50. The connection wiring line CNa may electrically connect the pixel driving unit PDC and the light emitting element LDa to each other. In other words, the connection wiring line CNa may electrically connect the connection transistor TR and the light emitting element LD to each other.

A sixth insulating layer 60a may be disposed on the fifth insulating layer 50 and the connection wiring line CNa. The sixth insulating layer 60a may cover a portion of the connection wiring line CNa. An opening OP1a (hereinafter, referred to as a first opening) through which at least a portion of the connection wiring line CNa is exposed may be defined in the sixth insulating layer 60a. For example, a portion of an upper surface of the connection wiring line CNa may be exposed through the first opening OP1a of the sixth insulating layer 60a. The connection wiring line CNa may be electrically connected to the light emitting element LDa through the portion thereof exposed from the sixth insulating layer 60a.

A light emitting element layer LDLa may be disposed on the sixth insulating layer 60a. The light emitting element layer LDLa may include the pixel definition film PDL, the metal layer DM, the light emitting element LDa, and the separator SPR. The pixel definition film PDL and the separator SPR of the light emitting element layer LDLa may be the same or substantially the same as the pixel definition film PDL and the separator SPR described above with reference to FIG. 5.

The light emitting opening OP-PDL through which at least a portion of the first electrode EL1 is exposed, and a second opening OP2a overlapping with the first opening OP1a of the sixth insulating layer 60a may be defined in the pixel definition film PDL. The light emitting opening OP-PDL may overlap with a portion of the first electrode EL1. The second opening OP2a may overlap with the portion of the connection wiring line CNa exposed by the first opening OP1a. A planar area of the second opening OP2 may be greater than a planar area of the first opening OP1. However, the present disclosure is not limited thereto, and the planer area of the second opening OP2 may be smaller than or equal to the planer area of the first opening OP1, as long as the portion of the connection wiring line CNa is exposed.

The metal layer DM may be disposed on the sixth insulating layer 60a and the pixel definition film PDL. Further, the metal layer DM may be disposed to overlap with the first opening OP1a of the sixth insulating layer 60a and the second opening OP2a of the pixel definition film PDL. The metal layer DM may be disposed so as not to overlap with the light emitting element LDa. The metal layer DM may cover the portion of the upper surface of the connection wiring line CNa exposed through the first opening OP1a. In other words, the metal layer DM may be in contact with the upper surface of the connection wiring line CNa, and may be electrically connected to the connection wiring line CNa.

The metal layer DM may be in contact with a side surface of the separator SPR. The metal layer DM may be formed to surround (e.g., around a periphery of) the separator SPR on a plane (e.g., in a plan view). After the metal layer DM is deposited and a portion of the metal layer DM is etched, the separator SPR may be formed to overlap with the removed etched portion.

The light emitting element LDa may include the first electrode EL1, an intermediate layer IMLa, and the second electrode EL2a. The first electrode EL1 may be disposed on the sixth insulating layer 60a. The first electrode EL1 of FIG. 7 may be the same or substantially the same as the first electrode EL1 described above with reference to FIG. 5.

The intermediate layer IMLa may be disposed between the first electrode EL1 and the second electrode EL2a. The intermediate layer IMLa may include the light emitting layer EML and a functional layer FNLa. The light emitting layer EML of FIG. 7 may be the same or substantially the same as the light emitting layer EML described above with reference to FIG. 5. Unlike the functional layer FNL described above with reference to FIG. 5, the functional layer FNLa of FIG. 7 may not include the one end IN1 (e.g., see FIG. 6) disposed along the upper surface of the fifth insulating layer 50, and the other end IN2 disposed along the upper surface of the connection wiring line CN (e.g., see FIG. 5). In other words, the functional layer FNLa may not include a shape cut by the tip portion TP (e.g., see FIG. 5).

The second electrode EL2a may be disposed on the intermediate layer IMLa. The second electrode EL2a may be connected to the connection wiring line CNa, and may be electrically connected to the pixel driving unit PDC. Unlike the second electrode EL2 described above with reference to FIG. 5, the second electrode EL2a of FIG. 7 may not include the one end EN1 (e.g., see FIG. 6) of the second electrode EL2 disposed along the upper surface of the fifth insulating layer 50, and the other end EN2 disposed along the upper surface of the connection wiring line CN (e.g., see FIG. 5). In other words, the second electrode EL2a may not include a shape cut by the tip portion TP (e.g., see FIG. 5).

The connection wiring line CNa may include the driving connection part CD and a light emitting connection part CEa. The driving connection part CD may be a part of the connection wiring line CNa that is connected to the pixel driving unit PDC, and a part connected to or substantially connected to the connection transistor TR. The light emitting connection part CEa may be a part of the connection wiring line CNa that is connected to the light emitting element LDa. The light emitting connection part CEa may be a part that is defined in an area exposed from the sixth insulating layer 60a, and to which the second electrode EL2a is connected. In this case, the light emitting connection part CEa may be defined on the upper surface of the connection wiring line CNa.

The connection wiring line CNa may include a first layer L1a, a second layer L2a, and a third layer L3a sequentially laminated in the third direction DR3. The first layer L1a and the third layer L3a may include titanium (Ti), and the second layer L2a may include aluminum (Al). However, the present disclosure is not limited thereto. Unlike the connection wiring line CN described above with reference to FIG. 5, the connection wiring line CNa may not include the tip portion TP. In other words, a side surface of the first layer L1a, a side surface of the second layer L2a, and a side surface of the third layer L3a may be aligned with each other. In this case, the light emitting connection part CEa may not be formed on the side surface L2_W (e.g., see FIG. 6) of the second layer L2 (e.g., see FIG. 5), and may be formed on an upper surface of the third layer L3a.

The metal layer DM may be disposed on the light emitting connection part CEa of the connection wiring line CNa, and may be electrically connected to the light emitting connection part CEa. The second electrode EL2a may also be disposed on a portion of the connection wiring line CNa, which is exposed by the first opening OP1a of the sixth insulating layer 60a. In other words, a portion of the second electrode EL2a may be disposed to overlap with the metal layer DM. The second electrode EL2a may be electrically connected to the connection wiring line CNa through the metal layer DM. In other words, the second electrode EL2a may be in contact with the metal layer DM disposed on the light emitting connection part CEa, and may receive the second power voltage VSS (e.g., see FIG. 2A).

According to one or more embodiments of the present disclosure, as the display panel DPa further includes the metal layer DM, the second electrode EL2a may be electrically connected to the connection wiring line CNa only through the contact with the metal layer DM. In other words, a contact area in which the second electrode EL2a may be connected to the connection wiring line CNa may be widened. Accordingly, the connection between the connection wiring line CNa and the second electrode EL2a may be more easily performed.

FIG. 8 is a cross-sectional view of a display panel DPb according to an embodiment of the present disclosure. In FIG. 8, the same or substantially the same elements as those described above with reference to FIGS. 4D, 5, and 7 are denoted with the same reference numerals and symbols, and thus, redundant description thereof may not be repeated.

Referring to FIG. 8, a sixth insulating layer 60b and the fifth insulating layer 50 may be disposed on the connection wiring line CNa. The sixth insulating layer 60b may cover a portion of the connection wiring line CNa. A first opening OP1b through which the at least a portion of the connection wiring line CNa is exposed may be defined in the sixth insulating layer 60b. For example, the portion of the upper surface of the connection wiring line CNa may be exposed through the first opening OP1b of the sixth insulating layer 60b.

The light emitting opening OP-PDL through which at least a portion of the first electrode EL1 is exposed, and a second opening OP2b not overlapping with the first opening OP1b of the sixth insulating layer 60b may be defined in the pixel definition film PDL.

The display panel DPb of FIG. 8 may further include the capping pattern CPP as compared to the display panel DPa illustrated in FIG. 7. The capping pattern CPP may be disposed on the sixth insulating layer 60b. Further, the capping pattern CPP may also be disposed on a partial area of the connection wiring line CN, which is exposed by the first opening OP1b of the sixth insulating layer 60b. For example, the capping pattern CPP may be disposed on the third layer L3a of the connection wiring line CNa exposed through the first opening OP1b. The capping pattern CPP may overlap with a portion of the connection wiring line CNa, and may specifically overlap with the light emitting connection part CEa.

As illustrated in FIG. 8, when viewed on a cross section, the capping pattern CPP may have an integral shape that is not partially disconnected. Even on a plane (e.g., in a plan view), the capping pattern CPP may have an integral shape connected as a whole within an area (e.g., see FIG. 4C) defined as a closed line by the separator SPR.

A metal layer DMa may be disposed on the pixel definition film PDL. Further, the metal layer DMa may be disposed to overlap with the second opening OP2b of the pixel definition film PDL. FIG. 8 illustratively shows that the second opening OP2b of the pixel definition film PDL and the first opening OP1b of the sixth insulating layer 60b do not overlap with each other, but the present disclosure is not limited thereto, and the second opening OP2b of the pixel definition film PDL and the first opening OP1b of the sixth insulating layer 60b may overlap with each other. The metal layer DMa may be disposed so as not to overlap with the light emitting element LDa.

The capping pattern CPP may include a conducive material. The capping pattern CPP may electrically connect the metal layer DMa and the connection wiring line CNa to each other. For example, the metal layer DMa may be in contact with the capping pattern CPP that covers the portion of the upper surface of the connection wiring line CNa on the sixth insulating layer 60b, and the metal layer DMa may be electrically connected to the light emitting connection part CEa. Accordingly, the second electrode EL2a may be electrically connected to the connection wiring line CN through the metal layer DMa and the capping pattern CPP. In more detail, the capping pattern CPP may be in contact with the upper surface of the third layer L3a of the connection wiring line CNa. Thereafter, the metal layer DMa may be in contact with the capping pattern CPP, the second electrode EL2a may be in contact with the metal layer DMa, and thus, all the components may be electrically connected to each other. The second electrode EL2a may be electrically connected to the capping pattern CPP and metal layer DMa arranged on the light emitting connection part CEa, and may receive the second power voltage VSS (e.g., see FIG. 2A).

According to one or more embodiments of the present disclosure, as the display panel DPb further includes the metal layer DMa and the capping pattern CPP, the second electrode EL2a may be electrically connected to the connection wiring line CNa only through the contact with the metal layer DM. In other words, a contact area in which the second electrode EL2a may be connected to the connection wiring line CNa may be widened. Accordingly, the connection between the connection wiring line CNa and the second electrode EL2a may be more easily performed.

Further, the capping pattern CPP may include a material having a relatively low reactivity as compared to the connection wiring line CNa. For example, the capping pattern CPP may include copper (Cu), silver (Ag), a transparent conductive oxide, or the like. As the upper surface of the connection wiring line CNa is protected by the capping pattern CPP having a relatively low reactivity, oxidation of the materials included in the third layer L3a may be prevented or substantially prevented. Further, in an etching process of patterning the first electrode EL1, a silver (Ag) component included in the first electrode EL1 may be reduced, and thus, a phenomenon in which the silver component remains as particles causing defects may be prevented or substantially prevented.

In an embodiment, the capping pattern CPP may be formed through the same process as that of the first electrode EL1, and may include the same material as that of the first electrode EL1. However, the present disclosure is not limited thereto, and the capping pattern CPP may be formed through a process different from that of the first electrode EL1, or may include a different material.

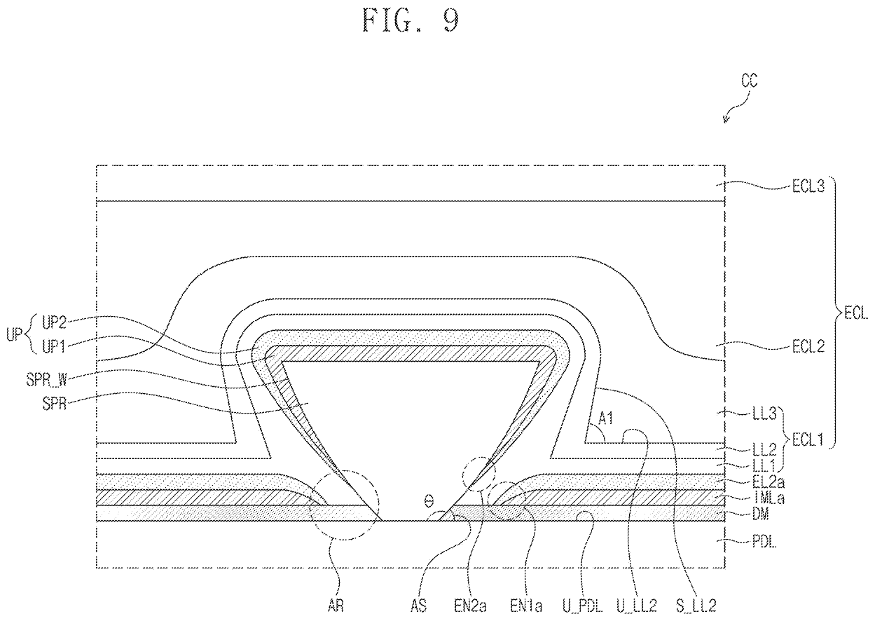

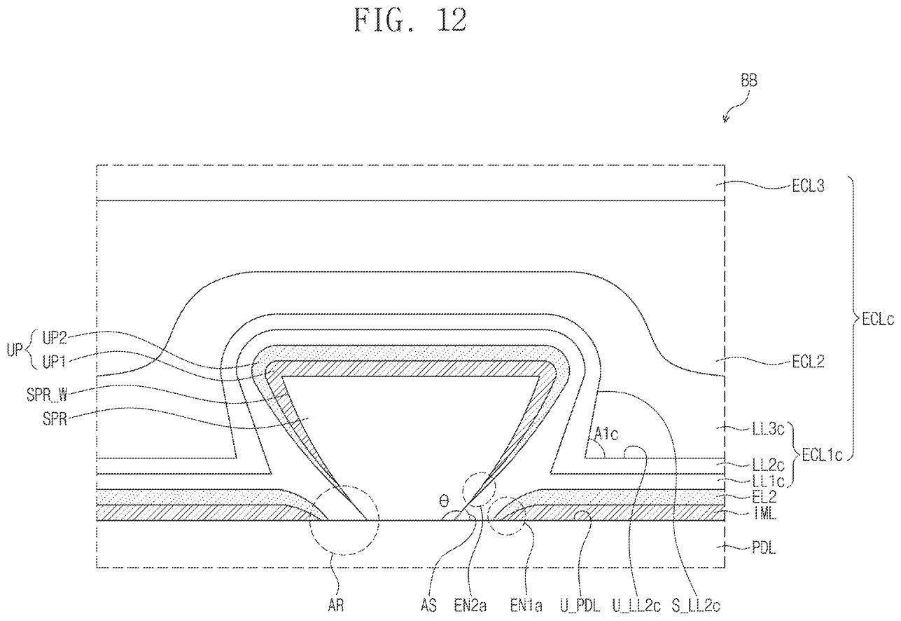

FIGS. 9 through 14 are enlarged cross-sectional views of a partial area of the display panel according to one or more embodiments of the present disclosure. FIGS. 9 to 11 are enlarged cross-sectional views illustrating the area CC of FIG. 7, and FIGS. 12 to 14 are enlarged cross-sectional views illustrating the area BB of FIG. 5. In FIGS. 9 to 14, the same or substantially the same elements as those described above with reference to FIGS. 1 to 8 are denoted by the same reference numerals and symbols, and thus, redundant description thereof may not be repeated.

Referring to FIGS. 9 to 14, the separator SPR may have a reverse tapered shape. An angle θ (hereinafter, referred to as a taper angle) between an upper surface of the pixel definition film PDL and a side surface SPR_W (e.g., an outer surface) of the separator SPR may be an obtuse angle. However, the present disclosure is not limited thereto, and the taper angle θ may be variously modified, as long as the separator SPR may electrically disconnect the second electrode EL2 or EL2a for each pixel. Further, the separator SPR may have the same or substantially the same structure as that of the tip portion TP, but the present disclosure is not limited thereto.

In an embodiment, the second electrode EL2 or EL2a may include a first end EN1a, and the second dummy layer UP2 may include a second end EN2a. The first end EN1a may be spaced apart from the separator SPR and positioned on the pixel definition film PDL. The second end EN2a may be separated from the first end EN1a and positioned on the side surface SPR_W of the separator SPR. While FIGS. 9 to 14 illustrate that the first end EN1a is spaced a distance (e.g., a predetermined distance) from the side surface SPR_W of the separator SPR, the present disclosure is not limited thereto, and the first end EN1a may be in contact with the side surface SPR_W of the separator SPR, as long as the first end EN1a is electrically disconnected from the second end EN2a. Further, even when the first end EN1a and the second end EN2a are connected without being distinguished from each other, when electrical resistance is high enough due to a small thickness of a portion of the separator SPR formed along the side surface SPR_W, and when the second electrode EL2 or EL2a is electrically disconnected between adjacent pixels, it may be considered that the second electrode EL2 or EL2a is divided by the separator SPR.

According to one or more embodiments of the present disclosure, even when there is no separate patterning process for the second electrode EL2 or EL2a or the intermediate layer IML or IMLa, the second electrode EL2 or EL2a or the intermediate layer IML or IMLa may not be formed on the side surface SPR_W of the separator SPR or may be formed to be thin, and thus, the second electrode EL2 or EL2a or the intermediate layer IML or IMLa may be divided for each pixel. Further, when the second electrode EL2 or EL2a or the intermediate layer IML or IMLa may be electrically disconnected between the adjacent pixels, the shape of the separator SPR may be variously deformed, but the present disclosure is not limited thereto.

Referring to FIG. 9, the encapsulation layer ECL may include the first encapsulation layer ECL1, the second encapsulation layer ECL2, and the third encapsulation layer ECL3. The first encapsulation layer ECL1 may include silicon carbonate (SiOCₓ). The first encapsulation layer ECL1 may include a first sub-layer LL1, a second sub-layer LL2, and a third sub-layer LL3 that cover the separator SPR. The second sub-layer LL2 may be disposed on the first sub-layer LL1, and the third sub-layer LL3 may be disposed on the second sub-layer LL2. However, the present disclosure is not limited thereto. For example, the first encapsulation layer ECL1 may include the first sub-layer LL1 and the second sub-layer LL2. In other words, the first encapsulation layer ECL1 may not include the third sub-layer LL3.

At least one of the first sub-layer LL1 and/or the second sub-layer LL2 may include an organic material, and the organic material may have flow characteristics and a low refractive index. For example, the organic material may be silicon carbonate (SiOCₓ). However, the present disclosure is not limited thereto, and the organic material included in the first sub-layer LL1 or the second sub-layer LL2 is not limited thereto.

A sub-layer not including the organic material from among the first to third sub-layers LL1, LL2, and LL3 may be an inorganic layer. The inorganic layer may include a silicon nitride layer, a silicon oxynitride layer, a silicon oxide layer, a titanium oxide layer, an aluminum oxide layer, or the like. The third sub-layer LL3 may include a different material from that of the second sub-layer LL2, but the present disclosure is not limited thereto. For example, the third sub-layer LL3 may include the same material as that of the second sub-layer LL2, and a refractive index of the third sub-layer LL3 and a refractive index of the second sub-layer LL2 may be different from each other. The second sub-layer LL2 and the third sub-layer LL3 may be distinguished from each other based on the refractive index.

The second encapsulation layer ECL2 may be disposed on the first encapsulation layer ECL1, and may include the organic material. The second encapsulation layer ECL2 may include an acryl-based organic layer, but the kind of material thereof is not particular limited.

The third encapsulation layer ECL3 may be disposed on the second encapsulation layer ECL2, and may include the inorganic material. The third encapsulation layer ECL3 may include a silicon nitride layer, a silicon oxynitride layer, a silicon oxide layer, a titanium oxide layer, or an aluminum oxide layer.

According to one or more embodiments of the present disclosure, as at least one of the first sub-layer LL1 and/or the second sub-layer LL2 includes the organic material, the first encapsulation layer ECL1 may gently cover the separator SPR. As a result, a gap (e.g., a boundary layer or seam) formed in a portion adjacent to a side surface of the separator SPR may be removed. Thus, a protection function of the encapsulation layer ECL, which protects the light emitting element LDa (e.g., see FIG. 7), may be improved, and display defects (e.g., dark spots) of the display device DD (e.g., see FIG. 1) may be reduced or removed.

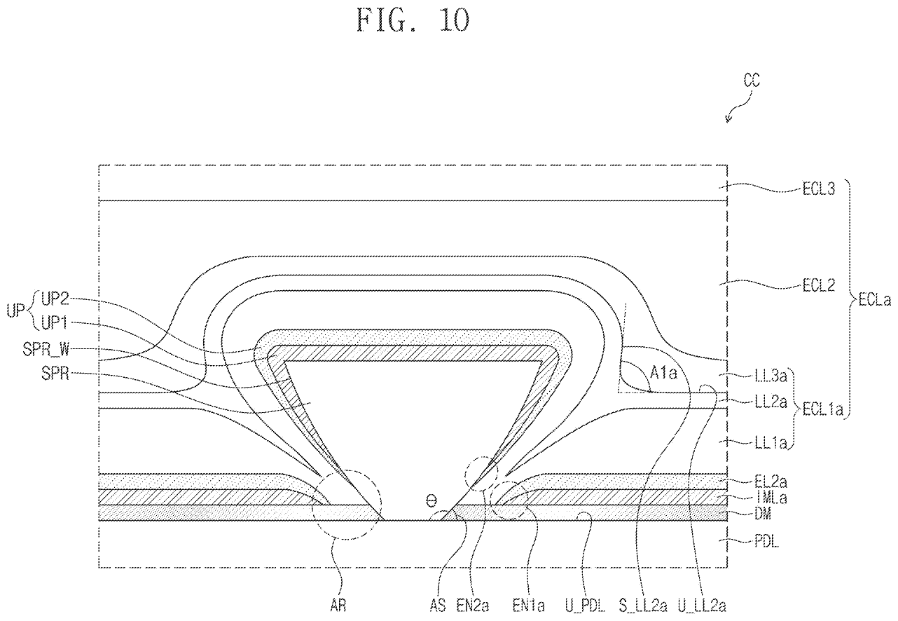

The above description of the encapsulation layer ECL, the first encapsulation layer ECL1, the second encapsulation layer ECL2, and the third encapsulation layer ECL3 may be equally applied to encapsulation layers ECLa, ECLb, ECLc, ECLd, or ECLe, first encapsulation layers ECL1a, ECL1b, ECL1c, ECL1d, or ECL1e, second encapsulation layers ECL2a, ECL2b, ECL2c, ECL2d, or ECL2e, third encapsulation layers ECL3a, ECL3b, ECL3c, ECL3d, or ECL3e illustrated in FIGS. 10 to 14.

Referring again to FIG. 9, the first sub-layer LL1 may include an organic material, and the organic material may have flow characteristics and a low refractive index. For example, the organic material may include silicon carbonate (SiOCₓ). The second sub-layer LL2 and the third sub-layer LL3 may include an inorganic material. For example, the inorganic material may include a silicon nitride layer, a silicon oxynitride layer, a silicon oxide layer, a titanium oxide layer, an aluminum oxide layer, or the like.

The first sub-layer LL1 may be disposed on the second electrode EL2a and the separator SPR. Further, the first sub-layer LL1 may also be disposed in an area AR (e.g., a region) in which the first end EN1a and the second end EN2a are spaced apart from each other. The first sub-layer LL1 may be disposed to be in contact with the metal layer DM disposed on the pixel definition film PDL. The first sub-layer LL1 may become thicker from the second electrode EL2a or the separator SPR toward the area AR in which the first end EN1a and the second end EN2a are spaced apart from each other.

An angle between an upper surface U_PDL of the pixel definition film PDL and the outer surface SPR_W of the separator SPR may be defined as an outer angle AS. An angle between an upper surface U_LL2 of the second sub-layer LL2 overlapping with the second electrode EL2a and a side surface S_LL2 of the second sub-layer LL2 formed along the outer surface SPR_W of the separator SPR may be defined as an angle A1. As the first sub-layer LL1 includes silicon carbonate (SiOCₓ) that is an organic material, the first sub-layer LL1 may cover the separator SPR more gently than the outer angle AS of the separator SPR. The angle A1 between the upper surface U_LL2 of the second sub-layer LL2 overlapping with the second electrode EL2a and the side surface S_LL2 of the second sub-layer LL2 formed along the outer surface SPR_W of the separator SPR may be greater than the outer angle AS between the upper surface U_PDL of the pixel definition film PDL and the outer surface SPR_W of the separator SPR.

The first sub-layer LL1 may have a small refractive index, and the second sub-layer LL2 may have a high refractive index as compared to that of the first sub-layer LL1. For example, the first sub-layer LL1 may have a refractive index of 1.30 or more and 1.45 or less, and the second sub-layer LL2 may have a refractive index of 1.5 or more. For example, the refractive index of the second sub-layer LL2 may be 1.89. However, the present disclosure is not limited thereto, and the refractive indexes of the first sub-layer LL1 and the second sub-layer LL2 are not limited thereto. As the first sub-layer LL1 and the second sub-layer LL2 have a low refractive index and a high refractive index, respectively, optical characteristics of the encapsulation layer ECL may be improved.

Referring to FIG. 10, an encapsulation layer ECLa may include first to third encapsulation layers ECL1a, ECL2, and ECL3. The first encapsulation layer ECL1a may include a first sub-layer LL1a, a second sub-layer LL2a disposed on the first sub-layer LL1a, and a third sub-layer LL3a disposed on the second sub-layer LL2a. The second sub-layer LL2a may include an organic material, and the organic material may have flow characteristics and a low refractive index. For example, the organic material may include silicon carbonate (SiOCₓ). The first sub-layer LL1a and the third sub-layer LL3a may include an inorganic material. For example, the inorganic material may include a silicon nitride layer, a silicon oxynitride layer, a silicon oxide layer, a titanium oxide layer, an aluminum oxide layer, or the like.

The first sub-layer LL1a may be disposed on the second electrode EL2a and the separator SPR. Further, the first sub-layer LL1a may also be disposed in the area AR in which the first end EN1a and the second end EN2a are spaced apart from each other. In other words, the first sub-layer LL1a may be disposed on the metal layer DM, the second electrode EL2a, and the separator SPR, and may cover the area AR between the second electrode EL2a and the separator SPR. The first sub-layer LL1a may be in contact with the metal layer DM disposed on the pixel definition film PDL. The first sub-layer LL1a may become thinner from the second electrode EL2a or the separator SPR toward the area AR in which the first end EN1a and the second end EN2a are spaced apart from each other.

The second sub-layer LL2a may cover the first sub-layer LL1a. For example, the second sub-layer LL2a may cover the first sub-layer LL1a disposed on the second electrode EL2a and the separator SPR and the first sub-layer LL1a disposed in the area AR in which the first end EN1a and the second end EN2a are spaced apart from each other. The second sub-layer LL2a may not be in contact with the metal layer DM. In this case, a thickness of the second electrode EL2a may be large. The second sub-layer LL2a may become thicker from a portion overlapping with the second electrode EL2a or the separator SPR toward the area AR in which the first end EN1a and the second end EN2a are spaced apart from each other.

As the second sub-layer LL2a includes silicon carbonate (SiOCx), the second sub-layer LL2a may cover the first sub-layer LL1a more gently than the outer angle AS of the separator SPR. An angle A1a between an upper surface U_LL2a of the second sub-layer LL2a overlapping with the second electrode EL2a and a side surface S_LL2a of the second sub-layer LL2a formed along the outer surface SPR_W of the separator SPR may be greater than the outer angle AS between the upper surface U_PDL of the pixel definition film PDL and the outer surface SPR_W of the separator SPR.

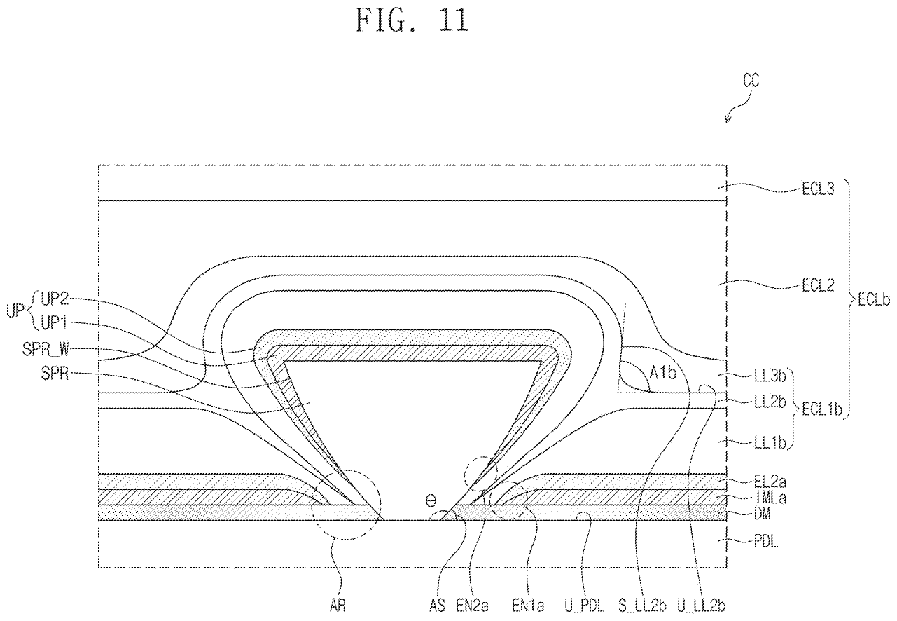

Referring to FIG. 11, an encapsulation layer ECLb may include first to third encapsulation layers ECL1b, ECL2, and ECL3. The first encapsulation layer ECL1b may include a first sub-layer LL1b, a second sub-layer LL2b disposed on the first sub-layer LL1b, and a third sub-layer LL3b disposed on the second sub-layer LL2b. The second sub-layer LL2b may include an organic material, and the organic material may have flow characteristics and a low refractive index. For example, the organic material may include silicon carbonate (SiOCₓ). The first sub-layer LL1b and the third sub-layer LL3b may include an inorganic material. For example, the inorganic material may include a silicon nitride layer, a silicon oxynitride layer, a silicon oxide layer, a titanium oxide layer, an aluminum oxide layer, or the like.

The first sub-layer LL1b may be disposed on the second electrode EL2a and the separator SPR. Further, the first sub-layer LL1b may also be disposed in the area AR in which the first end EN1a and the second end EN2a are spaced apart from each other. In other words, the first sub-layer LL1b may be disposed on the metal layer DM, the second electrode EL2a, and the separator SPR, and may cover a portion of the area AR between the second electrode EL2a and the separator SPR. The first sub-layer LL1b may be in contact with the metal layer DM disposed on the pixel definition film PDL. The first sub-layer LL1b may become thinner from the second electrode EL2a or the separator SPR toward the area AR in which the first end EN1a and the second end EN2a are spaced apart from each other.

The second sub-layer LL2b may cover the first sub-layer LL1b. For example, the second sub-layer LL2b may cover the first sub-layer LL1b disposed on the second electrode EL2a and the separator SPR and the first sub-layer LL1b disposed in the area AR in which the first end EN1a and the second end EN2a are spaced apart from each other. The second sub-layer LL2b may be in contact with the metal layer DM in the area AR between the second electrode EL2a and the separator SPR. For example, the second sub-layer LL2b may cover a portion other than a portion covered by the first sub-layer LL1b. In this case, a thickness of the second electrode EL2a may be small. The second sub-layer LL2b may become thicker from a portion overlapping with the second electrode EL2a or the separator SPR toward the area AR in which the first end EN1a and the second end EN2a are spaced apart from each other.

As the second sub-layer LL2b includes silicon carbonate (SiOCx), the second sub-layer LL2b may cover the first sub-layer LL1b more gently than the outer angle AS of the separator SPR. An angle A1b between an upper surface U_LL2b of the second sub-layer LL2b overlapping with the second electrode EL2a and a side surface S_LL2b of the second sub-layer LL2b formed along the outer surface SPR_W of the separator SPR may be greater than the outer angle AS between the upper surface U_PDL of the pixel definition film PDL and the outer surface SPR_W of the separator SPR.

Referring to FIG. 12, an encapsulation layer ECLc may include first to third encapsulation layers ECL1c, ECL2, and ECL3. The first encapsulation layer ECL1c may include a first sub-layer LL1c, a second sub-layer LL2c disposed on the first sub-layer LL1c, and a third sub-layer LL3c disposed on the second sub-layer LL2c. The first sub-layer LL1c may include an organic material, and the organic material may have flow characteristics and a low refractive index. For example, the organic material may include silicon carbonate (SiOCₓ). The second sub-layer LL2c and the third sub-layer LL3c may include an inorganic material. For example, the inorganic material may include a silicon nitride layer, a silicon oxynitride layer, a silicon oxide layer, a titanium oxide layer, an aluminum oxide layer, or the like.

The first sub-layer LL1c may be disposed on the second electrode EL2 and the separator SPR. Further, the first sub-layer LL1c may also be disposed in the area AR in which the first end EN1a and the second end EN2a are spaced apart from each other. The first sub-layer LL1c may be in contact with the pixel definition film PDL. The first sub-layer LL1c may become thicker from the second electrode EL2 or the separator SPR toward the area AR in which the first end EN1a and the second end EN2a are spaced apart from each other.

As the first sub-layer LL1c includes silicon carbonate (SiOCₓ) that is an organic material, the first sub-layer LL1c may cover the separator SPR more gently than the outer angle AS of the separator SPR. An angle A1c between an upper surface U_LL2c of the second sub-layer LL2c overlapping with the second electrode EL2 and a side surface S_LL2c of the second sub-layer LL2c formed along the outer surface SPR_W of the separator SPR may be greater than the outer angle AS between the upper surface U_PDL of the pixel definition film PDL and the outer surface SPR_W of the separator SPR.

The first sub-layer LL1c may have a small refractive index, and the second sub-layer LL2c may have a high refractive index as compared to that of the first sub-layer LL1c. For example, the first sub-layer LL1c may have a refractive index of 1.30 or more and 1.45 or less, and the second sub-layer LL2c may have a refractive index of 1.5 or more. For example, the refractive index of the second sub-layer LL2 may be 1.89. However, the present disclosure is not limited thereto, and the refractive indexes of the first sub-layer LL1c and the second sub-layer LL2c are not limited thereto. As the first sub-layer LL1c and the second sub-layer LL2c have a low refractive index and a high refractive index, respectively, optical characteristics of the encapsulation layer ECLc may be improved.

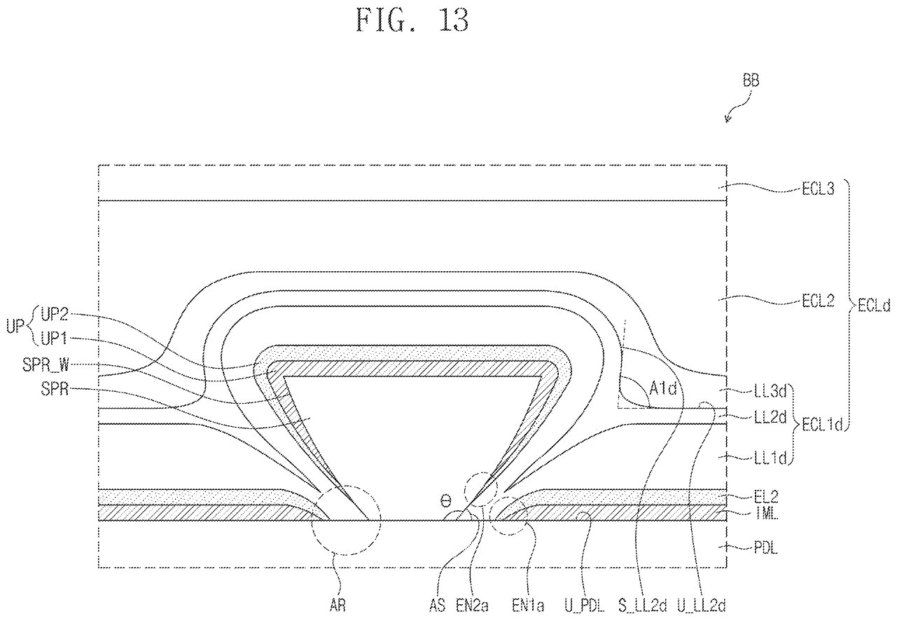

Referring to FIG. 13, an encapsulation layer ECLd may include first to third encapsulation layers ECL1d, ECL2, and ECL3. The first encapsulation layer ECL1d may include a first sub-layer LL1d, a second sub-layer LL2d disposed on the first sub-layer LL1d, and a third sub-layer LL3d disposed on the second sub-layer LL2d. The second sub-layer LL2d may include an organic material, and the organic material may have flow characteristics and a low refractive index. For example, the organic material may include silicon carbonate (SiOCₓ). The first sub-layer LL1d and the third sub-layer LL3d may include an inorganic material. For example, the inorganic material may include a silicon nitride layer, a silicon oxynitride layer, a silicon oxide layer, a titanium oxide layer, an aluminum oxide layer, or the like.

The first sub-layer LL1d may be disposed on the second electrode EL2 and the separator SPR. Further, the first sub-layer LL1d may also be disposed in the area AR in which the first end EN1a and the second end EN2a are spaced apart from each other. In other words, the first sub-layer LL1d may be disposed on the pixel definition film PDL, the second electrode EL2, and the separator SPR to cover the area AR. The first sub-layer LL1d may be in contact with the pixel definition film PDL. The first sub-layer LL1d may become thinner from the second electrode EL2 or the separator SPR toward the area AR in which the first end EN1a and the second end EN2a are spaced apart from each other.

The second sub-layer LL2d may cover the first sub-layer LL1d. For example, the second sub-layer LL2d may cover the first sub-layer LL1d disposed on the second electrode EL2 and the separator SPR and the first sub-layer LL1d disposed in the area AR in which the first end EN1a and the second end EN2a are spaced apart from each other. The second sub-layer LL2d may not be in contact with the pixel definition film PDL. In this case, a thickness of the second electrode EL2 may be large. The second sub-layer LL2d may become thicker from a portion overlapping with the second electrode EL2 or the separator SPR toward the area AR in which the first end EN1a and the second end EN2a are spaced apart from each other.

As the second sub-layer LL2d includes silicon carbonate (SiOCx), the second sub-layer LL2d may cover the first sub-layer LL1d more gently than the outer angle AS of the separator SPR. An angle A1d between an upper surface U_LL2d of the second sub-layer LL2d overlapping with the second electrode EL2 and a side surface S_LL2d of the second sub-layer LL2d formed along the outer surface SPR_W of the separator SPR may be greater than the outer angle AS between the upper surface U_PDL of the pixel definition film PDL and the outer surface SPR_W of the separator SPR.

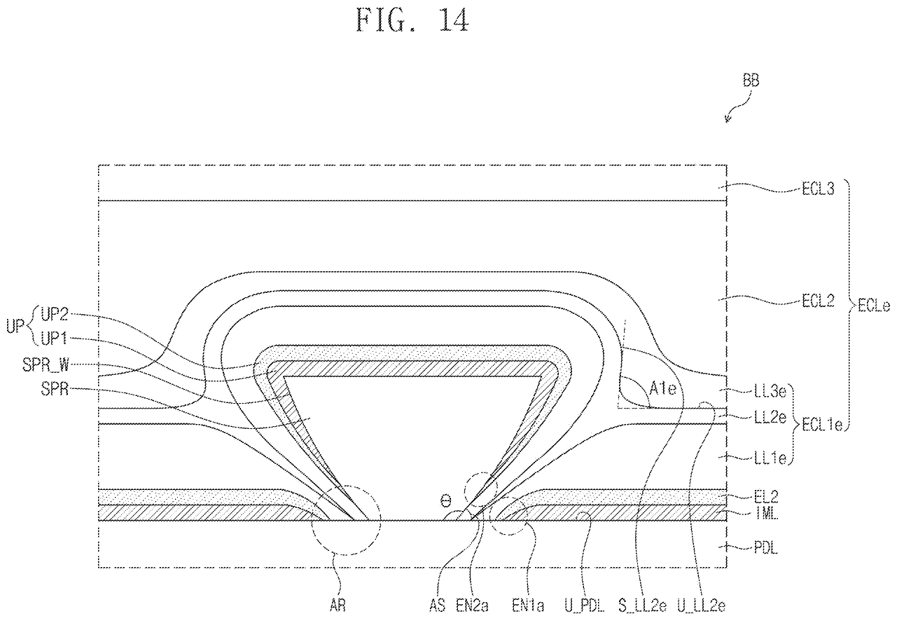

Referring to FIG. 14, an encapsulation layer ECLe may include first to third encapsulation layers ECL1e, ECL2, and ECL3. The first encapsulation layer ECL1e may include a first sub-layer LL1e, a second sub-layer LL2e disposed on the first sub-layer LL1e, and a third sub-layer LL3e disposed on the second sub-layer LL2e. The second sub-layer LL2e may include an organic material, and the organic material may have flow characteristics and a low refractive index. For example, the organic material may include silicon carbonate (SiOCₓ). The first sub-layer LL1e and the third sub-layer LL3e may include an inorganic material. For example, the inorganic material may include a silicon nitride layer, a silicon oxynitride layer, a silicon oxide layer, a titanium oxide layer, an aluminum oxide layer, or the like.

The first sub-layer LL1e may be disposed on the second electrode EL2 and the separator SPR. Further, the first sub-layer LL1e may also be disposed in the area AR in which the first end EN1a and the second end EN2a are spaced apart from each other. In other words, the first sub-layer LL1e may be disposed on the pixel definition film PDL, the second electrode EL2, and the separator SPR to cover a portion of the area AR. The first sub-layer LL1e may be in contact with the pixel definition film PDL. The first sub-layer LL1e may become thinner from the second electrode EL2 or the separator SPR toward the area AR in which the first end EN1a and the second end EN2a are spaced apart from each other.

The second sub-layer LL2e may cover the first sub-layer LL1e. For example, the second sub-layer LL2e may cover the first sub-layer LL1e disposed on the second electrode EL2 and the separator SPR and the first sub-layer LL1e disposed in the area AR in which the first end EN1a and the second end EN2a are spaced apart from each other. The second sub-layer LL2b may be in contact with the pixel definition film PDL in the area AR between the second electrode EL2 and the separator SPR. For example, the second sub-layer LL2e may cover a portion other than a portion covered by the first sub-layer LL1e. In this case, a thickness of the second electrode EL2 may be small. The second sub-layer LL2e may become thicker from a portion overlapping with the second electrode EL2 or the separator SPR toward the area AR in which the first end EN1a and the second end EN2a are spaced apart from each other.

As the second sub-layer LL2e includes silicon carbonate (SiOCx), the second sub-layer LL2e may cover the first sub-layer LL1e more gently than the outer angle AS of the separator SPR. An angle Ale between an upper surface U_LL2e of the second sub-layer LL2e overlapping the second electrode EL2 and a side surface S_LL2e of the second sub-layer LL2e formed along the outer surface SPR_W of the separator SPR may be greater than the outer angle AS between the upper surface U_PDL of the pixel definition film PDL and the outer surface SPR_W of the separator SPR.

As described above, as at least one of a first sub-layer and/or a second sub-layer of a first encapsulation layer directly covering a separator may include an organic material, the first encapsulation layer may gently cover the separator. As a result, a gap (e.g., a boundary layer or seam) formed in a portion adjacent to a side surface of the separator may be removed. Thus, a protection function of an encapsulation layer that protects a light emitting element may be improved, and display defects (e.g., dark spots or the like) of a display device may be reduced or removed.

Further, as a display panel may further include a metal layer, a second electrode may be electrically connected to a connection wiring line only through contact with the metal layer. In other words, a contact area in which the second electrode may be connected to the connection wiring line may be widened. Accordingly, the connection between the connection wiring line and the second electrode may be more easily performed.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a base layer;
a light emitting element on the base layer, and comprising a first electrode, an intermediate layer on the first electrode, and a second electrode on the intermediate layer;
a pixel definition film on the first electrode, and having a light emitting opening exposing a portion of the first electrode;
a separator on the pixel definition film, and disconnecting the second electrode; and
an encapsulation layer on the pixel definition film, and comprising:
a first encapsulation layer comprising a first sub-layer covering the separator, a second sub-layer on the first sub-layer, and a third sub-layer on the second sub-layer;
a second encapsulation layer on the first encapsulation layer, and comprising an organic material; and
a third encapsulation layer on the second encapsulation layer, and comprising an inorganic material,
wherein at least one of the first sub-layer or the second sub-layer comprises an organic material.

2. The display device of claim 1, wherein the first encapsulation layer comprises silicon carbonate (SiOCₓ).

3. The display device of claim 1, wherein the first sub-layer comprises silicon carbonate (SiOCₓ), and the second sub-layer and the third sub-layer comprise the inorganic material.

4. The display device of claim 1, wherein the second sub-layer comprises silicon carbonate (SiOCₓ), and the first sub-layer and the third sub-layer comprise the inorganic material.

5. The display device of claim 1, further comprising:
a transistor; and
a connection wiring line connecting the transistor and the light emitting element to each other, and comprising a first layer, a second layer, and a third layer,
wherein a side surface of the third layer forms a tip portion protruding from a side surface of the second layer, and the second electrode is disconnected by the tip portion.

6. The display device of claim 5, wherein the first sub-layer is located on the pixel definition film, the second electrode, and the separator to cover an area between the second electrode and the separator.

7. The display device of claim 5, wherein the second sub-layer is in contact with the pixel definition film in an area between the second electrode and the separator.

8. The display device of claim 1, further comprising:
a transistor;
a connection wiring line connecting the transistor and the light emitting element to each other; and
a metal layer between the pixel definition film and the intermediate layer,
wherein the metal layer is electrically connected to the connection wiring line.

9. The display device of claim 8, wherein the first sub-layer is located on the metal layer, the second electrode, and the separator to cover an area between the second electrode and the separator.

10. The display device of claim 8, wherein the second sub-layer is in contact with the metal layer in an area between the second electrode and the separator.

11. The display device of claim 8, wherein the metal layer surrounds the separator in a plan view.

12. The display device of claim 8, further comprising a capping pattern on the transistor, the capping pattern comprising the same material as that of the first electrode,
wherein the capping pattern electrically connects the metal layer and the connection wiring line to each other.

13. The display device of claim 1, wherein an angle between an upper surface of the second sub-layer overlapping with the second electrode and a side surface of the second sub-layer along an outer surface of the separator is greater than an outer angle between an upper surface of the pixel definition film and the outer surface of the separator.

14. A display device comprising:
a base layer;
a transistor;
a light emitting element on the base layer, and comprising a first electrode, an intermediate layer on the first electrode, and a second electrode on the intermediate layer;
a connection wiring line connecting the transistor and the light emitting element to each other;
a pixel definition film on the first electrode, and having a light emitting opening exposing a portion of the first electrode;
a separator on the pixel definition film, and disconnecting the second electrode;
a metal layer on the pixel definition film, and surrounding the separator in a plan view; and
an encapsulation layer on the pixel definition film, and comprising:
a first encapsulation layer comprising silicon carbonate (SiOCₓ);
a second encapsulation layer on the first encapsulation layer, and comprising an organic material; and
a third encapsulation layer on the second encapsulation layer, and comprising an inorganic material.

15. The display device of claim 14, wherein the first encapsulation layer comprises a first sub-layer covering the separator, a second sub-layer on the first sub-layer, and a third sub-layer on the second sub-layer, and
wherein at least one of the first sub-layer or the second sub-layer comprises the silicon carbonate (SiOCₓ).

16. The display device of claim 15, wherein the first sub-layer comprises the silicon carbonate (SiOCₓ), and the second sub-layer and the third sub-layer comprise inorganic materials.

17. The display device of claim 15, wherein the second sub-layer comprises the silicon carbonate (SiOCₓ), and the first sub-layer and the third sub-layer comprise inorganic materials.

18. The display device of claim 15, wherein the first sub-layer is located on the metal layer, the second electrode, and the separator to cover an area between the second electrode and the separator.

19. The display device of claim 15, wherein the second sub-layer is in contact with the metal layer in an area between the second electrode and the separator.

20. A display device comprising:
a base layer;
a light emitting element on the base layer, and comprising a first electrode, an intermediate layer on the first electrode, and a second electrode on the intermediate layer;
a pixel definition film on the first electrode, and having a light emitting opening exposing a portion of the first electrode;
a separator on the pixel definition film, and disconnecting the second electrode; and
an encapsulation layer on the pixel definition film, and comprising a first encapsulation layer, a second encapsulation layer, and a third encapsulation layer stacked in a thickness direction of the base layer,
wherein the first encapsulation layer comprises a first sub-layer, a second sub-layer, and a third sub-layer sequentially stacked in the thickness direction of the base layer, and at least one of the first sub-layer or the second sub-layer comprises silicon carbonate (SiOCₓ), and
wherein an angle between an upper surface of the second sub-layer overlapping with the second electrode and a side surface of the second sub-layer along an outer surface of the separator is greater than an outer angle between an upper surface of the pixel definition film and the outer surface of the separator.
